(19) United States
(12) Patent Application Publication
(10) Pub. No.: US 2023/0395884 A1
(43) Pub. Date: Dec. 7, 2023

(54) DEGRADATION SUPPRESSION SYSTEM

(71) Applicant: DENSO CORPORATION, Kariya-city (JP)

(72) Inventors: Ryo OTA, Kariya-city (JP); Sho NAGASHIMA, Kariya-city (JP)

(21) Appl. No.: 18/453,711

(22) Filed: Aug. 22, 2023

Related U.S. Application Data
(63) Continuation of application No. PCT/JP22/01288, filed on Jan. 17, 2022.

(30) Foreign Application Priority Data
Feb. 26, 2021 (JP) 2021-029385

(51) Int. Cl. H01M 10/48; G01R 31/392; H01M 10/42; H01M 10/63; B60L 58/16

(52) U.S. Cl. CPC H01M 10/48; G01R 31/392; H01M 10/425; H01M 2220/20; B60L 58/16; H01M 2010/4271; H01M 10/63

(57) ABSTRACT

The degradation suppression system includes a secondary battery, a usage history acquisition unit, a degradation amount estimation unit, a degradation factor identification unit, and a suppression control unit. The usage history acquisition unit acquires usage history information indicating the usage history of the secondary battery. The degradation amount estimation unit estimates the degradation amount of the secondary battery by using the usage history information acquired by the usage history acquisition unit. The degradation factor identification unit uses the usage history information to identify multiple degradation factors relating to the degradation amount, of the secondary battery, estimated by the degradation amount estimation unit. The suppression control unit controls the secondary battery to suppress the secondary battery degradation according to the configuration of degradation factors of the secondary battery degradation.

### CROSS REFERENCE TO RELATED APPLICATION

The present application is a continuation application of International Patent Application No. PCT/JP2022/001288 filed on Jan. 17, 2022, which designated the U.S. and claims the benefit of priority from Japanese Patent Application No. 2021-029385 filed on Feb. 26, 2021. The entire disclosures of all of the above applications are incorporated herein by reference.

### TECHNICAL FIELD

The present disclosure relates to a degradation suppression system configured to suppress deterioration of a secondary battery.

### BACKGROUND

Conventionally, a secondary battery has been used in various apparatuses such as a vehicle.

### SUMMARY

According to an aspect of the present disclosure, a degradation suppression system comprises a secondary battery and a control unit. The control unit is configured to acquire information on the secondary battery and control the secondary battery based on the information as acquired.

### BRIEF DESCRIPTION OF THE DRAWINGS

The above and other objects, features and advantages of the present disclosure will become more apparent from the following detailed description made with reference to the accompanying drawings. In the drawings:

The above and other objects, features, and advantages of the present disclosure will become more apparent from the following detailed description made by reference to the accompanying drawings. In the drawings:

FIG. 1 is an overall configuration diagram illustrating the degradation suppression system according to a first embodiment;

FIG. 2 is a flowchart relating to a degradation suppression process according to the first embodiment;

FIG. 3 is a flowchart relating to the calculation of the battery states according to the first embodiment;

FIG. 4 is an explanatory diagram schematically illustrating the relationship among the open-circuit voltage, the closed-circuit voltage, and the SOC of a secondary battery before degradation;

FIG. 5 is an explanatory diagram schematically illustrating the relationship among the open-circuit voltage, the closed-circuit voltage, and the SOC of a secondary battery after degradation;

FIG. 6 is an explanatory diagram relating to the impact of degradation states on the advance of future degradation;

FIG. 7 is an explanatory diagram relating to the calculation of an optimum average temperature according to the first embodiment;

FIG. 8 is a diagram illustrating a temperature adjustment request map according to the first embodiment;

FIG. 9 is an explanatory diagram relating to the effects of the degradation suppression control in the degradation suppression system;

FIG. 10 is a flowchart relating to a degradation suppression process according to the second embodiment;

FIG. 11 is an explanatory diagram illustrating the relationship between the degradation suppression control according to the second embodiment and outputs from the secondary battery;

FIG. 12 is an explanatory diagram illustrating the relationship between the degradation suppression control according to the second embodiment and the battery temperature of the secondary battery;

FIG. 13 is a flowchart relating to a degradation suppression process according to the third embodiment;

FIG. 14 is an explanatory diagram illustrating the relationship between the degradation amount of the secondary battery and the current rate;

FIG. 15 is an explanatory diagram illustrating changes in an input/output range due to the degradation suppression control according to a third embodiment;

FIG. 16 is a schematic diagram illustrating the connection of a refrigeration cycle device and an inverter to the secondary battery;

FIG. 17 is an explanatory diagram relating to the amount of electric power input to the secondary battery when the degradation suppression control according to a fourth embodiment is not provided;

FIG. 18 is an explanatory diagram relating to the amount of electric power input to the secondary battery when the degradation suppression control according to the fourth embodiment is provided;

FIG. 19 is a flowchart relating to the degradation suppression process according to a fifth embodiment;

FIG. 20 is a flowchart relating to post-processing according to the fifth embodiment; and

FIG. 21 is an overall configuration diagram of the degradation suppression system according to a sixth embodiment.

### DETAILED DESCRIPTION

Hereinafter, examples of the present disclosure will be described.

According to an example of the present disclosure, a configuration is employed to manage a temperature of a secondary battery to be within a predetermined range to make the most of the performance of the secondary battery. More specifically, according to an example of the present disclosure, a configuration is employed that compares a current degradation amount of a secondary battery with a degradation amount required from the life design line and intensifies a cooling to adjust the temperature of the secondary battery when the deviation amount between both is greater than or equal to a threshold value. The configuration causes a temperature frequency distribution of the secondary battery to decline toward the low temperature, thereby to enable to suppress advancing deterioration due to an increased temperature of the secondary battery.

The secondary battery degradation includes a calendar degradation and a cycle degradation. The calendar degradation advances degradation according to an increase in the temperature. The cycle degradation advances degradation due to energization at a low temperature. The cycle degradation advances according to the energization of the secondary battery. The secondary battery degradation may advance variously depending on how the secondary battery is used. A large difference is supposed between the percentage of the calendar degradation and that of the cycle degradation.

In a presumable configuration, the temperature of the secondary battery may decrease when the cycle degradation is dominant in terms of the secondary battery degradation. Then, the advance of cycle degradation may be accelerated to advance the secondary battery degradation. The presumable configuration may not provide an appropriate control to suppress the advance of degradation referring to the degradation state of the secondary battery and may accelerate the secondary battery degradation.

According to an example of the present disclosure, a degradation suppression system comprises:
a secondary battery;
a usage history acquisition unit configured to acquire usage history information indicating a usage history of the secondary battery;
a degradation amount estimation unit configured to estimate a degradation amount of the secondary battery by using the usage history information acquired by the usage history acquisition unit;
a degradation factor identification unit configured to identify a plurality of degradation factors, which relates to the degradation amount of the secondary battery, by using the usage history information, in terms of the degradation amount of the secondary battery estimated by the degradation amount estimation unit; and
a suppression control unit configured to perform a control on the secondary battery to suppress the degradation of the secondary battery according to a configuration of the degradation factors of the degradation of the secondary battery.

It is possible to control the secondary battery and suppress degradation of the secondary battery in a more appropriate mode taking into account the configuration of multiple degradation factors of the secondary battery degradation in addition to the degradation amount occurring on the secondary battery.

The description below explains embodiments for carrying out the present disclosure by reference to the drawings. The same reference numerals are given to parts in each embodiment similar to those described in the preceding embodiment and a redundant description may be omitted for simplicity. If only part of a configuration in each embodiment is described, other parts in the configuration may conform to those described in the preceding embodiment. Each embodiment may contain parts that are explicitly described to be capable of combination. In addition to the combination of these parts, the embodiments can be partially combined, if possible, with each other even if the embodiments are not explicitly described to be capable of the combination.

### First Embodiment

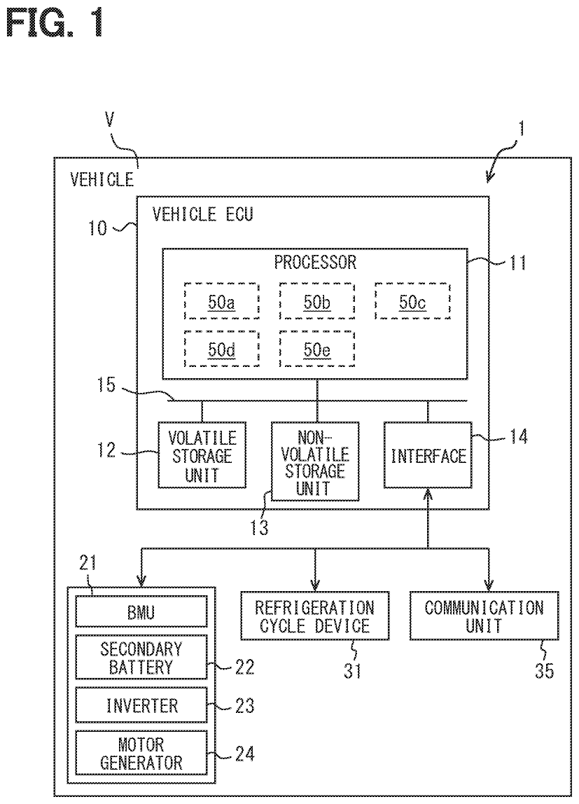

The description below explains the first embodiment according to the present disclosure by reference to FIGS. 1 through 4. The present embodiment applies a degradation suppression system 1 according to the present disclosure to a vehicle V such as an electric vehicle that is equipped with a secondary battery and uses an electric motor to generate a driving force for running. The degradation suppression system 1 according to the first embodiment determines the degradation state of the secondary battery 22 mounted on the vehicle V as well as degradation factors and provides appropriate degradation suppression control to inhibit future degradation from advancing.

The vehicle V mounted with the secondary battery 22 can be applied to not only an electric vehicle but also a hybrid vehicle. According to the first embodiment, the secondary battery 22 is placed under the floor of the vehicle V, for example, and is used as a power source for parts (such as a rotary electric machine) of the vehicle V.

The secondary battery 22 includes multiple battery cells connected in series. For example, the secondary battery 22 is configured as a battery pack including multiple battery modules each of which includes multiple battery cells placed in a row. For example, the battery cell is configured as a lithium-ion secondary battery.

The negative electrode of the secondary battery 22 is composed of a negative-electrode active material such as graphite that can absorb and release lithium ions. The positive electrode of the secondary battery 22 is available as a ternary electrode containing Ni, Mn, and Co such as LiNi_{1/3}Co_{1/3}Mn_{1/3}O₂. The electrode may be made of a composite material. The secondary battery 22 may be configured in such a manner as connecting battery cells in parallel to form a cell block and connecting the cell blocks in series.

As illustrated in FIG. 1, the degradation suppression system 1 includes a vehicle ECU 10, a BMU 21, a secondary battery 22, an inverter 23, a motor generator 24, a refrigeration cycle device 31, and a communication unit 35.

The vehicle ECU 10 is composed of a well-known microcomputer and its peripheral circuits. For example, the microcomputer includes a processor 11, a volatile storage portion 12 functioning as an operation area, a non-volatile storage portion 13 to store various control programs, and an interface 14. The processor 11, the volatile storage portion 12, the non-volatile storage portion 13, and the interface 14 are connected via a bus 15.

The vehicle ECU 10 uses the processor 11 to perform various calculations and processes based on the control program stored in the non-volatile storage portion 13 and controls operations of various devices connected via the interface 14.

The interface 14 connects with the BMU 21, the secondary battery 22, the inverter 23, and the motor generator 24. The BMU (Battery Management Unit) 21, manages the usage history of the secondary battery 22, for example. The BMU 21 practices the management relating to power input/output from the secondary battery 22.

The inverter 23 changes direct current to alternating current. The motor generator 24, when powered, outputs driving force for traveling and generates a regenerative electric power during deceleration, for example. The vehicle V can allow the inverter 23 to convert regenerative power generated by the motor generator 24 during deceleration and thereby charge the secondary battery 22.

As illustrated in FIG. 1, the interface 14 connects with the refrigeration cycle device 31 and the communication unit 35. The refrigeration cycle device 31 configures a part of the vehicle interior air conditioner of the vehicle V and also configures a temperature adjustment device for the secondary battery 22. The refrigeration cycle device 31 configures a vapor-compression subcritical refrigeration cycle in which the pressure of the high-pressure refrigerant discharged from the compressor does not exceed the critical pressure of the refrigerant.

The refrigeration cycle device 31 includes a compressor, a condenser, and a decompression portion as well as an evaporator and a battery heat exchanger. The evaporator decreases the heat of the air blown into the passenger compartment by causing a low-pressure refrigerant to absorb the heat. The battery heat exchanger cools the secondary battery 22 by providing heat exchange between the secondary battery 22 and the low-pressure refrigerant. The communication unit 35 enables two-way communication of data with the outside of the vehicle V via network N.

As illustrated in FIG. 1, functional portions of the degradation suppression system 1 include a usage history acquisition unit 50a, a degradation amount estimation unit 50b, a degradation factor identification unit 50c, a suppression control unit 50d, and a degradation prediction unit 50e. The usage history acquisition unit 50a is a functional portion that acquires usage history information indicating the usage history of the secondary battery 22 from the BMU 21. For example, the usage history acquisition unit 50a is configured as the vehicle ECU 10 to perform step S1 described later.

The degradation amount estimation unit 50b is a functional portion that estimates the degradation amount in the secondary battery 22 by using the usage history information about the secondary battery 22. For example, the degradation amount estimation unit 50b is configured as the vehicle ECU 10 to perform steps S3 and S4 described later.

The degradation factor identification unit 50c is a functional portion that uses usage history information to identify degradation factors (such as calendar degradation and cycle degradation) relating to the degradation amount of the secondary battery 22, estimated by the degradation amount estimation unit 50b. For example, the degradation factor identification unit 50c is configured as the vehicle ECU 10 to perform step S5 described later.

The suppression control unit 50d is a functional portion that controls the secondary battery 22 to suppress the degradation of the secondary battery 22 according to the configuration of degradation factors in the degradation of the secondary battery 22. For example, the suppression control unit 50d is configured as the vehicle ECU 10 to perform steps S6 to S8.

The degradation prediction unit 50e is a functional portion that predicts the future degradation amount of the secondary battery 22 based on the degradation characteristics of the secondary battery 22, identified by the usage history information acquired by the usage history acquisition unit 50a. For example, the degradation prediction unit 50e is configured as the vehicle ECU 10 to perform step S6.

In terms of the vehicle ECU 10, the configuration to control the BMU 21, the secondary battery 22, the inverter 23, and the motor generator 24 is comparable to a movement manager that controls the movement functions of the vehicle V. In terms of the vehicle ECU 10, the configuration to control the refrigeration cycle device 31 is comparable to a heat manager that controls the heat management in the vehicle V.

At least one of the functions of the degradation suppression system 1 may be configured by an electronic circuit (hardware) to implement the corresponding function.

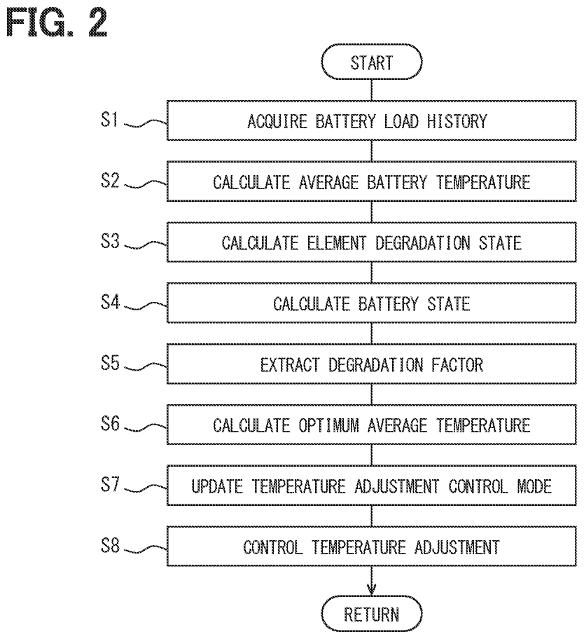

The description below explains the steps of the degradation suppression process in the degradation suppression system 1 according to the first embodiment by reference to the flowchart in FIG. 2.

In step S1, the process acquires the battery load history of the secondary battery 22 used in the vehicle V from the BMU 21 of the vehicle V via the interface 14. The battery load history is comparable to usage history information. The degradation suppression system 1 can thereby acquire the battery load history of the secondary battery 22 without disassembling the secondary battery 22 (battery pack).

It may be favorable to provide the arithmetic function of the BMU 12 for a device (such as a data server) other than the vehicle V and use the device as part of the degradation suppression system 1. Step S1 just needs to be able to acquire the battery load history of the secondary battery 22, not limited to the acquisition from the BMU 21.

The battery load history as usage history information includes the history of loads acting on the secondary battery 22, such as battery temperature T as the temperature of the secondary battery 22, a charge-discharge current, and the duration of use, for example. These pieces of history information are acquired from the BMU 21 and are then stored in the volatile storage portion 12 or the non-volatile storage portion 13.

In step S2, the process uses battery temperature T of the secondary battery 22 included in the battery load history to calculate average battery temperature Ta as an average value for temperatures of the secondary battery 22 during a predetermined period. Average battery temperature Ta is the average value for battery temperature T over the entire period including a period indicating no input/output to the secondary battery 22 and a period indicating input/output to the secondary battery 22. Average battery temperature Ta is an example of the period-based average temperature.

After proceeding to step S3, the process uses the acquired battery load history to calculate element degradation states SOHQₐe, SOHQ_{c}e, SOHQ_{Li}e, SOHRₐe, and SOHR_{c}e of the secondary battery 22 mounted on the vehicle V. SOH stands for State Of Health.

SOHQₐe is the capacity retention rate for the negative electrode of the secondary battery 22 at the present moment. SOHQ_{c}e is the capacity retention rate for the positive electrode of the secondary battery 22 at the present moment. SOHQ_{Li}e is the capacity retention rate for the electrolyte of the secondary battery 22 at the present moment. SOHRₐe is the resistance increase rate for the negative electrode of the secondary battery 22 at the present moment. SOHR_{c}e is the resistance increase rate for the positive electrode of the secondary battery 22 at the present moment.

The capacity retention rate of each component (such as negative electrode, positive electrode, and electrolyte) of the secondary battery 22 at a predetermined time (any time after the start of use) represents the ratio of the capacity of each component at the predetermined time to the capacity of each component of the secondary battery 22 in the initial state (such as factory shipment). A negative electrode capacity corresponds to the number of negative electrode sites capable of lithium ion insertion. A positive electrode capacity corresponds to the number of positive electrode sites capable of lithium ion insertion.

The electrolyte capacity is expressed through the use of a positive/negative electrode SOC misalignment capacity. The positive/negative electrode SOC misalignment capacity denotes a difference between the capacity regions used for the positive electrode and the negative electrode in the secondary battery 22. The positive/negative electrode SOC misalignment capacity corresponds to the number of lithium ions movable between the positive electrode and the negative electrode as well as the ease of movement of the entire lithium ion.

The resistance increase rate at a predetermined time (any time after the start of temporary use) of each component of the secondary battery 22 represents the ratio of the resistance value of each component at the predetermined time to the resistance value of each component of the secondary battery 22 in the initial state.

The degradation suppression system 1 calculates each of the element degradation states SOHQₐe, SOHQ_{c}e, SOHQ_{Li}e, SOHRₐe, and SOHR_{c}e based on multiple degradation factors relating to each cell component. The degradation suppression system 1 calculates the element degradation states SOHQₐe and SOHRₐe relating to the negative electrode based on multiple degradation factors of the negative electrode of the secondary battery 22. The degradation suppression system 1 also calculates the element degradation states SOHQ_{c}e and SOHR_{c}e for the positive electrode based on multiple degradation factors of the positive electrode. Furthermore, the degradation suppression system 1 calculates the element degradation state SOHQ_{Li}e for the electrolyte based on multiple electrolyte degradation factors.

Specifically, each of the negative electrode capacity Qₐ and the negative electrode resistance Ra is calculated in consideration of: the degradation factor caused by the formation of a film on the plane of the active material; the degradation factor caused by cracking of a film formed on the plane of the active material; and the degradation factor caused by cracking of the active material itself.

Each of the positive electrode capacity Q_{c} and the positive electrode resistance R_{c} is calculated in consideration of: the degradation factor caused by surface alteration of the active material; the degradation factor caused by cracking of the altered plane of the active material; and the degradation factor in consideration of cracking of the active material itself.

The element degradation state SOHQ_{Li}e of the electrolyte is calculated in consideration of: the degradation factor caused by the formation of a film on the surface of the active material of the negative electrode; the degradation factor caused by cracking of the film formed on the surface of the active material of the negative electrode; and the degradation factor caused by cracking of the active material itself of the negative electrode. The element degradation state SOHQ_{Li}e of the electrolyte is calculated further in consideration of: the degradation factor caused by the formation of a film on the surface of the active material of the positive electrode; the degradation factor caused by cracking of the film formed on the surface of the active material of the positive electrode; and the degradation factor caused by cracking of the active material itself of the positive electrode.

Details of how to calculate the element degradation states will be described later.

In step S4, the process calculates the battery states SOHQ_{B}e and SOHR_{B}e, that is, the degradation states of the entire secondary battery 22 mounted on the vehicle V. The battery state SOHQ_{B}e represents the degradation state of the entire secondary battery 22 in terms of the capacity of the secondary battery 22. The battery state SOHQ_{B}e is derived by taking the minimum value of the element degradation states SOHQₐe, SOHQ_{c}e, and SOHQ_{Li}e calculated in step S3. It is possible to express SOHQ_{B}e=min (SOHQₐe, SOHQ_{c}e, SOHQ_{Li}e).

As described above, the negative electrode capacity Qₐ corresponds to the number of negative electrode sites capable of lithium ion insertion. The positive electrode capacity Q_{c} corresponds to the number of positive electrode sites capable of lithium ion insertion. The positive/negative electrode SOC misalignment capacity Q_{Li} corresponds to the number of lithium ions movable between the positive electrode and the negative electrode as well as the ease of movement of the entire lithium ion.

The minimum of the negative electrode capacity Qₐ, the positive electrode capacity Q_{c}, and the positive/negative electrode SOC misalignment capacity Q_{Li} corresponds to the battery capacity Q_{B} of the secondary battery 22. The minimum value of the element degradation states SOHQₐe, SOHQ_{c}e, and SOHQ_{Li}e represents the battery state SOHQ_{B}e of the entire secondary battery 22.

The battery state SOHR_{B}e represents the degradation state of the entire secondary battery 22 in terms of resistance. Battery state SOHR_{B}e is calculated as the sum of the element degradation states SOH Rae and SOH Rce. It is possible to express SOHR_{B}e=SOHRₐe+SOHR_{c}e.

For example, suppose the element degradation state takes into account the resistance of a member (such as an electrolyte) other than the electrodes (negative and positive) of the secondary battery 22. Then the calculation of the battery state SOHR_{B}e takes into account the element degradation state of that member. The element degradation state relating to the member is added to the right side of SOHR_{B}e=SOHRₐe+SOHR_{c}e.

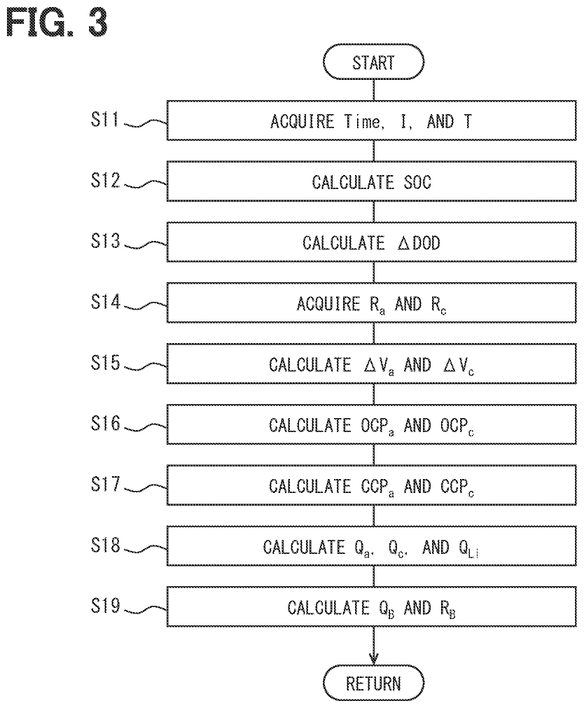

By reference to FIG. 3, the description below explains, in detail, the calculation of the element degradation state in step S3 and the calculation of the battery state in step S4. In step S3, as above, the degradation suppression system 1 sequentially calculates element degradation states of the secondary battery 22 from the start of use to the present time based on the battery load history of the secondary battery 22.

In the following description, ts denotes the start time to start calculating the element degradation state per one time and te denotes the end time. The time from the start time ts to the end time te is referred to as an operation cycle. The length of the implementation cycle is appropriately determined in consideration of the accuracy of prediction of the element degradation state and the battery state and a computational load on the calculation of the element degradation state and the battery state.

In step S11, the process acquires the battery load history, that is, the battery temperature T, the charge-discharge current value I, and the duration of use Time. The processing contents of step S11 correspond to step S1 in FIG. 2. At this time, the degradation suppression system 1 calculates the battery temperature T of the secondary battery 22 during the operation cycle based on the temperature distribution of the secondary battery 22 during the operation cycle. The battery temperature T can use an average value calculated from the frequency distribution of the temperature of the secondary battery 22 acquired during the operation cycle, for example.

To reduce the computational load, the battery temperature T can use the average temperature of secondary battery 22 acquired during the operation cycle. The battery temperature T is stored in the volatile storage portion 12 or the non-volatile storage portion 13 of the degradation suppression system 1.

In step S12, the degradation suppression system 1 calculates the integrated value of the current value I of the secondary battery 22 and calculates the state of charge of the secondary battery 22 based on the calculated integrated value. The state of charge (SOC) is the ratio of the remaining capacity to the full charge capacity of the secondary battery 22, expressed as a percentage. The state of charge of the secondary battery 22 is hereinafter referred to as SOC. The degradation suppression system 1 calculates the SOC of the secondary battery 22 based on the integrated value of the current values of the secondary battery 22 through the use of a current integration method, for example.

In step S13, the degradation suppression system 1 calculates ΔDOD. ΔDOD is calculated by a difference between the SOC at the start time is and the SOC at the end time to in the operation cycle. DOD stands for Depth Of Discharge representing the depth of discharge of the secondary battery 22.

In step S14, the degradation suppression system 1 calculates the negative electrode resistance Rₐ and the positive electrode resistance R_{c} of the secondary battery 22. The negative electrode resistance Rₐ is calculated based on the battery temperature T of the secondary battery 22, the current value I of the secondary battery 22, the SOC change amount ΔDOD, and the closed circuit potential of the negative electrode of the secondary battery 22. The positive electrode resistance R_{c} is calculated based on the battery temperature T of the secondary battery 22, the current value I of the secondary battery 22, the SOC change amount ΔDOD, and the closed-circuit potential of the positive pole.

The battery temperature T corresponds to the battery temperature T of the secondary battery 22 as calculated in step S11. The current value I corresponds to the current value I of the secondary battery 22 as calculated in step S11. The amount of change ΔDOD corresponds to the ΔDOD as calculated in step S13.

Closed-circuit potentials for the negative and positive electrodes of the secondary battery 22 correspond to those for the negative and positive electrodes of the secondary battery 22 calculated during the previous operation cycle. Hereafter, the closed circuit potential for the negative electrode of the secondary battery 22 is referred to as CCPₐ. The closed-circuit potential for the positive electrode of the secondary battery 22 is referred to as CCP_{c}. CCP stands for Closed Circuit Potential.

The negative electrode resistance Ra can be expressed as a function of the battery temperature T, the negative-electrode closed circuit potential CCPₐ, the change amount ΔDOD, and the charge-discharge current value I of the secondary battery 22. The positive electrode resistance R_{c} can be expressed as a function of the temperature T, the positive-electrode-side closed circuit potential CCP_{c}, the amount of change ΔDOD, and the charge-discharge current value I of the secondary battery 22. This is explained below.

The negative electrode resistance Rₐ increases due to the formation of a film (SEI: Solid Electrolyte Interface) on the negative electrode plane as a result of oxidation-reduction decomposition of the electrolyte and its additives for the secondary battery 22. The above-described chemical reaction generates the film. Therefore, the negative electrode resistance Rₐ follows the Arrhenius rule. The negative electrode resistance Rₐ can be expressed as a function of the battery temperature T.

The film formation on the negative electrode plane is caused by oxidation-reduction and therefore follows the Tafel law. The negative electrode resistance Rₐ can be expressed as a function of the negative-electrode-side closed circuit potential CCPₐ.

When the charge/discharge cycle of the secondary battery 22 is repeated, the active material of the negative electrode repeatedly expands and contracts to advance cracks in the plane coating. The negative electrode surface is eventually exposed through cracks in the coat. The amount of coating increases as a new coat is formed on the plane exposed from the crack. Consequently, the negative electrode resistance Rₐ further increases. An increase in the amount of change ΔDOD increases the degree of expansion and contraction of the active material. Therefore, the negative electrode resistance Rₐ can be expressed as a function of the amount of change ΔDOD.

At the negative electrode, the active material repeatedly expands and contracts to crack the active material itself and decrease the diameter. Cracking of the active material itself includes a factor to decrease the negative electrode resistance Rₐ and a factor to increase the negative electrode resistance Rₐ.

Cracking of the active material itself generates a new plane (no coat formed) on the active material, thus increasing the reaction area. Cracking of the active material itself is a factor in decreasing the negative electrode resistance Rₐ. When a new plane is formed on the active material, the coat formation is promoted on the new plane. The amount of coating increases to increase the negative electrode resistance Rₐ. In consideration of the above, the negative electrode resistance Rₐ can be expressed as a function of the amount of change ΔDOD based on the theory described below.

The pulverization rate, that is, the rate of cracking in the active material of the negative electrode, is expressed as dr/dt, where r denotes the particle diameter of the active material and t denotes the time. The pulverization rate dr/dt is considered to easily advance in conformity with an increase in the particle diameter r of the active material. The pulverization speed dr/dt can be considered to be proportional to the particle size r of the active material. Therefore, the pulverization speed dr/dt can be expressed as equation (1) below.

$$\begin{matrix}[ Math . 1 ] & \\ \frac{dr}{dt} = - k \times r & ( 1 )\end{matrix}$$

In equation (1), k is a constant, hereinafter also referred to as a pulverization coefficient, when appropriate. The equation is solved and is expressed as equation (2) below.

[Math. 2]

ln(r)=−k×t+α (2)

In equation (2), α is a constant.

The active material expands and contracts more actively in conformity with an increase in the amount of change ΔDOD. The pulverization constant is considered to be proportional to the amount of change ΔDOD. Then, equation (3) below is true.

[Math. 3]

ln(k)=β×ΔDOD+γ (3)

In equation (3), β and γ are constants. The equation is solved and is expressed as equation (4) below.

[Math. 4]

k=η×exp(ζ×ΔDOD) (4)

In equation (4), η and ζ are constants. Equations (2) and (4) are coupled to derive equations (5) and (6) below.

[Math. 5, 6]

r(t,ΔDOD)=r₀{1−A×exp[B×<exp(C×ΔDOD)>×t]} (5)

r(t,ΔDOD)≡A×exp[B×<exp(C×ΔDOD)>×t] (6)

In the equation, r₀ denotes the initial radius (t=0) of the active material, and A, B, and C denote constants. As above, the negative electrode resistance Rₐ increases due to the formation of a coat on the negative electrode surface. The coat formation rate on the negative electrode surface correlates with the diameter of the active material for the negative electrode. Therefore, the negative electrode resistance Rₐ can be expressed by an equation including the pulverization function f(t, ΔDOD), that is, a function of ΔDOD. The inside of each parenthesis at the right side in equation (5) may be further corrected by adding a constant.

Cracking of the negative electrode's surface coat and active material itself also depends on the charge-discharge current value I of the secondary battery 22. The current tends to flow intensively through a low-resistance part of the active material according to an increase in the charge-discharge current value I. There may occur a difference in the degree of expansion and contraction depending on parts of the active material. Strain easily occurs in the active material, causing cracks in the negative electrode's and active material itself.

Cracking of the negative electrode's plane coat and active material itself can be expressed as a function of the charge-discharge current value I or a C-rate function correlated with the charge-discharge current value I. In terms of constant-current charge/discharge measurements, the one C rate indicates a current value that fully charges or discharges the rated capacity of the battery in an hour.

To summarize the above, the negative electrode resistance Rₐ is expressed by equation (7) below, through the use of function g_{A}(T, CCPₐ), function g_{B}(T, CCPₐ, ΔDOD, I), and function g_{C}(T, CCPₐ, ΔDOD, I).

Function g_{A}(T, CCPₐ) considers the formation of a coat on the active material surface. Function g_{B}(T, CCPₐ, ΔDOD, I) considers cracking in the coat formed on the active material surface. Function g_{C}(T, CCPₐ, ΔDOD, I) considers cracking in the active material itself.

[Math. 7]

Rₐ=g_{A}(T,CCPₐ)×g_{B}(T,CCPₐ,ΔDOD,I)×g_{C}(T,CCPₐ,ΔDOD,I) (7)

Based on the above-described theory, negative electrode resistance Rₐ is expressed as a function of the battery temperature T, the negative-electrode-side closed circuit potential CCPₐ, the change amount ΔDOD, and the charge-discharge current value I of the secondary battery 22.

The positive electrode resistance R_{c} will be explained. The positive electrode resistance R_{c} increases correspondingly to the deterioration of the positive electrode surface. The positive electrode surface deteriorates through chemical reactions. The positive electrode resistance R_{c} then conforms to the Arrhenius law. Therefore, the positive electrode resistance R_{c} can be expressed as a function of the battery temperature T.

The deterioration of the positive electrode surface is caused by the reductive decomposition of the positive electrode surface and therefore conforms to Tafel law. The positive electrode resistance R_{c} can be expressed as a function of the positive-electrode-side closed circuit potential CCP_{c}.

The charge/discharge cycle of the secondary battery 22 is repeated. The active material of the positive electrode is repeatedly expanded and contracted. Eventually, a crack occurs on the surface of the deteriorated positive-electrode active material, thus forming a new, uncorrupted positive electrode surface. The new positive electrode surface deteriorates to further increase the positive electrode resistance R_{c}. An increase in the amount of change ΔDOD increases the degree of expansion and contraction of the active material. The positive electrode resistance R_{c} can be expressed as a function of the amount of change ΔDOD.

The deterioration of the positive electrode surface advances by repeatedly expanding and contracting the active material of the positive electrode to advance cracking in the active material of the positive electrode, and decreasing the diameter of the active material. Cracking of the active material itself includes a factor to decrease the positive electrode resistance R_{c} and a factor to increase the positive electrode resistance R_{c}.

Cracking of the active material itself generates a new plane (before deterioration) on the active material and becomes a factor to decrease the positive electrode resistance R_{c}. A new surface, when formed on the active material, eventually deteriorates to increase the positive electrode resistance R_{c}. In consideration of the above, the positive electrode resistance R_{c} can be expressed by equation (6) including pulverization function f(t, ΔDOD), that is, the function of ΔDOD, based on the same theory as the negative electrode resistance Rₐ.

Cracking of the positive electrode's active material itself also depends on the charge-discharge current value I. The current tends to flow intensively through a low-resistance part of the active material according to an increase in the charge-discharge current value I. There may occur a difference in the degree of expansion and contraction depending on parts of the active material. Strain easily occurs in the active material itself, causing cracks in the positive electrode's active material itself. Cracking of the positive electrode's active material itself can be expressed as a function of the charge-discharge current value I or a C-rate function correlated with the charge-discharge current value I.

To summarize the above, the positive electrode resistance R_{c} is expressed by equation (8) below, through the use of function h_{A}(T, CCP_{c}), function h_{B}(T, CCP_{c}, ΔDOD, I), and h_{C}(T, CCP_{c}, ΔDOD, I).

Function h_{A}(T, CCP_{c}) considers the surface deterioration of the active material. Function h_{B}(T, CCP_{c}, ΔDOD, I) considers cracking of the deteriorated surface of the active material. Function h_{C}(T, CCP_{c}, ΔDOD, I) considers cracking in the active material itself.

[Math. 8]

R_{c}=h_{A}(T,CCP_{c})×h_{B}(T,CCP_{c},ΔDOD,I)×h_{C}(T,CCP_{c},ΔDOD,I) (8)

Based on the above-described theory, positive electrode resistance R_{c} is expressed as a function of the battery temperature T, the negative-electrode-side closed circuit potential CCP_{c}, the change amount ΔDOD, and the charge-discharge current value I of the secondary battery 22.

In step S14, the negative-electrode-side closed circuit potential CCPₐ and the positive-electrode-side closed circuit potential CCP_{c}, used to calculate the negative electrode resistance Rₐ and the positive electrode resistance R_{c}, use the negative-electrode-side closed circuit potential CCPₐ and the positive-electrode-side closed circuit potential CCP_{c} in the most recent operation cycle but one. The negative-electrode-side closed circuit potential CCPₐ and the positive-electrode-side closed circuit potential CCP_{c} are calculated in step S17 in the immediately preceding operation cycle.

At system startup, for example, the negative-electrode-side closed circuit potential CCPₐ and positive-electrode-side closed circuit potential CCP_{c} calculated in the previous operation cycle may be unavailable. In such a case, initial negative-electrode-side closed circuit potential CCPₐ and positive-electrode-side closed circuit potential CCP_{c} are calculated as follows.

An initial polarization ΔVₐ of the negative electrode is calculated from the product of the current value I calculated in step S11 and the initial value of the negative electrode resistance Rₐ. An initial polarization ΔV_{c} of the positive electrode is calculated from the product of the current value I calculated in step S11 and the initial value of the positive electrode resistance R_{c}. The initial values of the negative electrode resistance Rₐ and the positive electrode resistance R_{c} are comparable to those in the initial state (such as factory shipment) relating to secondary batteries of the same type as the secondary battery 22 installed in the vehicle V, for example.

The initial values for the negative electrode resistance and the positive electrode resistance of the secondary battery 22 are maintained in the BMU 21 and can be acquired from the BMU 21, for example. The electrode resistance Rₐ and the positive electrode resistance R_{c} in the initial state can be determined by the AC impedance method or IV measurement, for example. Alternatively, the electrode resistance Rₐ and the positive electrode resistance R_{c} in the initial state can be also determined by creating a half cell using the positive electrode and a half cell using the negative electrode of the disassembled secondary battery 22 in the initial state and measuring the resistance of each half cell.

The open-circuit potentials of the negative and positive electrodes of the secondary battery are calculated based on the initial OCP characteristics (described later) and the SOC calculated in step S12. Each open-circuit potential corresponds to each electrode of the secondary battery 22 under the condition that the secondary battery 22 and the external circuit are not energized for a long period. Hereafter, the open circuit potential of the negative electrode of the secondary battery 22 is referred to as negative-electrode open circuit potential OCPₐ. The open circuit potential of the positive electrode of the secondary battery 22 is referred to as positive-electrode open circuit potential OCP_{c}. OCP stands for Open Circuit Potential.

The initial OCP characteristics indicate relationships relating to the secondary battery 22 in the initial state, such as: the relationship between the SOC and the negative-electrode open circuit potential OCPₐ; and the relationship between the SOC and the positive-electrode open circuit potential OCP_{c}. The initial OCP characteristics are stored in the BMU 21, for example.

The negative-electrode open circuit potential OCPₐ and the negative-electrode polarization ΔVₐ are added to acquire the negative-electrode closed circuit potential CCPₐ. The positive-electrode open circuit potential OCP_{c} and the positive-electrode polarization ΔV_{c} are added to acquire the positive-electrode closed circuit potential CCP_{c}.

At system startup, for example, the negative-electrode closed circuit potential CCPₐ and the positive-electrode closed circuit potential CCP_{c} calculated in the previous operation cycle may be unavailable. In such a case, the above-described process calculates the initial negative-electrode closed circuit potential CCPₐ and the positive-electrode closed circuit potential CCP_{c}.

The negative electrode resistance Rₐ and the positive electrode resistance R_{c} are calculated according to the above-described theory. Control then proceeds to step S15. The degradation suppression system 1 calculates the negative electrode polarization ΔVₐ and the positive electrode polarization ΔV_{c}. The negative electrode polarization ΔVₐ is calculated by multiplying the current value I of the secondary battery 22 calculated in step S11 by the negative electrode resistance Rₐ calculated in step S14. The positive electrode polarization ΔV_{c} is calculated by multiplying the current value I of the secondary battery 22 by the positive electrode resistance R_{c} calculated in step S14.

The degradation suppression system 1 proceeds to step S16 and calculates the negative-electrode open circuit potential OCPₐ and the positive-electrode open circuit potential OCP_{c}. The degradation suppression system 1 calculates the negative-electrode open circuit potential OCPₐ and the positive-electrode open circuit potential OCP_{c} based on the SOC of the secondary battery 22 calculated in step S12 and updated OCP characteristics, stored in the BMU 12, in the previous operation cycle. The updated OCP characteristics indicate relationships relating to the degraded secondary battery 22, such as: the relationship between the SOC and the negative-electrode open circuit potential OCPₐ; and the relationship between the SOC and the positive-electrode open circuit potential OCP_{c}.

The updated OCP characteristics can be acquired as follows. The process updates initial OCP properties previously stored in the volatile storage portion 12 or the non-volatile storage portion 13 of the degradation suppression system 1 based on the negative electrode capacity Qₐ, the positive electrode capacity Q_{c}, and the positive/negative electrode SOC misalignment capacity Q_{Li} calculated in step S18 described later.

The initial OCP characteristics indicate relationships relating to the secondary battery 22 in the initial state, such as: the relationship between the SOC and the negative-electrode open circuit potential OCPₐ; and the relationship between the SOC and the positive-electrode open circuit potential OCP_{c}. The method of updating the initial OCP characteristics is not particularly limited and is capable of adopting a known method, for example.

In step S17, the degradation suppression system 1 calculates the negative-electrode closed circuit potential CCPₐ and the positive-electrode closed circuit potential CCP_{c} of the secondary battery 22. The degradation suppression system 1 acquires the polarization ΔVₐ and the polarization ΔV_{c} calculated in step S15 and acquires the negative-electrode open circuit potential OCPₐ and the positive-electrode open circuit potential OCP_{c} calculated in step S16.

The negative-electrode closed circuit potential CCPₐ is calculated by adding the negative-electrode open circuit potential OCPₐ and the negative electrode polarization ΔVₐ. The negative-electrode open circuit potential OCPₐ can be rewritten to the negative-electrode closed circuit potential CCPₐ. Similarly, the positive-electrode closed circuit potential CCP_{c} is calculated by adding the positive-electrode open circuit potential OCP_{c} and the positive electrode polarization ΔV_{c}. The positive-electrode open circuit potential OCP_{c} can be rewritten to the positive-electrode closed circuit potential CCP_{c}.

Degradation actualizes the polarization of the secondary battery 22. An occurrence of polarization increases the closed circuit voltage of the secondary battery 22 during charging of the secondary battery 22 and decreases the same during discharging. As the secondary battery 22 deteriorates, the closed circuit voltage further increases during charging of the secondary battery 22 and further decreases during discharging.

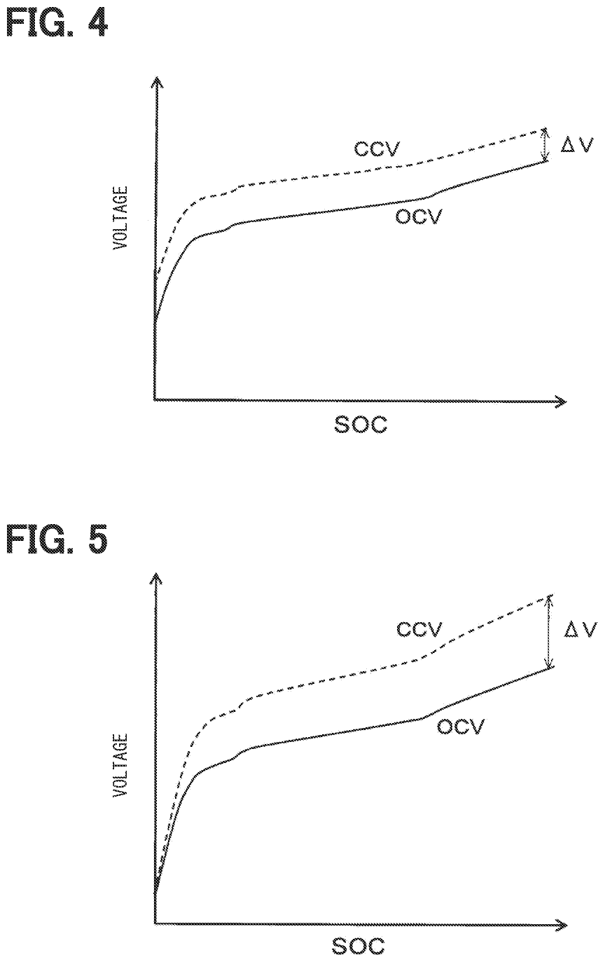

This will be explained by using FIGS. 4 and 5. FIG. 4 schematically illustrates the relationship between the SOC and the voltage during charging in terms of the secondary battery 22 before degradation. FIG. 5 schematically illustrates the relationship between the SOC and the voltage during charging in terms of the secondary battery 22 after degradation. In FIGS. 4 and 5, it is assumed that the solid line represents the open circuit voltage, the dashed line represents the closed circuit voltage, and the voltage on the vertical axis uses the same scale.

Hereinafter, the open circuit voltage is referred to as OCV and the closed circuit voltage is referred to as CCV. OCV stands for Open Circuit Voltage, and CCV stands for Closed Circuit Voltage.

FIGS. 4 and 5 show that the polarization ΔV of the secondary battery 22 after degradation is larger than the polarization ΔV before degradation. In consideration of this, the degradation suppression system 1 estimates the degradation amount of secondary battery 22 in such a manner that the open circuit potential OCP is rewritten to the closed circuit potential CCP considering the polarization ΔV and the closed circuit potential CCP is used to predict the battery capacity Q_{B}.

In step S18, the degradation suppression system 1 calculates the negative electrode capacity Qₐ, positive electrode capacity Q_{c}, and positive/negative electrode SOC misalignment capacity Q_{Li} of the secondary battery 22. The degradation suppression system 1 acquires the negative-electrode closed circuit potential CCPₐ and the positive-electrode closed circuit potential CCP_{c} calculated in step S17, the battery temperature T of the secondary battery 22 calculated in step S11, and the amount of change ΔDOD calculated in step S13.

In terms of the secondary battery 22, the degradation suppression system 1 calculates the negative electrode capacity Qₐ, the positive electrode capacity Q_{c}, and the positive/negative electrode SOC misalignment capacity Q_{Li} based on at least the negative-electrode closed circuit potential CCPₐ or the positive-electrode closed circuit potential CCP_{c}, the battery temperature T, the current value I, and the amount of change ΔDOD.

The description below explains the calculation of the negative electrode capacity Qₐ. The degradation suppression system 1 expresses the negative electrode capacity Qₐ based on the same theory as calculating the negative electrode resistance Rₐ. The negative electrode capacity Qₐ is represented by equation (9) below through the use of function i_{A}(T, CCPₐ), function i_{B}(T, CCPₐ, ΔDOD, I), and function i_{C}(T, CCPₐ, ΔDOD, I).

Function i_{A}(T, CCPₐ) considers the formation of a coat on the active material surface. Function i_{B}(T, CCPₐ, ΔDOD, I) considers cracking in the coat formed on the active material surface. The function i_{C}(T, CCPₐ, ΔDOD, I) considers the cracking of the active material itself. The negative electrode capacity Qₐ is expressed as a function of the battery temperature T, the negative-electrode closed circuit potential CCPₐ, the change amount ΔDOD (or pulverization function f(t, ΔDOD)), and the charge-discharge current value I of the secondary battery 22.

[Math. 9]

Qₐ=i_{A}(T,CCPₐ)×i_{B}(T,CCPₐ,ΔDOD,I)×i_{C}(T,CCPₐ,ΔDOD,I) (9)

Next, the description below explains the calculation of the negative electrode capacity Q_{c}. The degradation suppression system 1 expresses the positive electrode capacity Q_{c} based on the same theory as calculating the positive electrode resistance R_{c}. The positive electrode capacity Q_{c} is represented by equation (10) below through the use of function j_{A}(T, CCP_{c}), function j_{B}(T, CCP_{c}, ΔDOD, I), and function j_{C}(T, CCP_{c}, ΔDOD, I).

Function j_{A}(T, CCP_{c}) considers the surface deterioration of the active material. Function j_{B}(T, CCP_{c}, ΔDOD, I) considers cracking of the deteriorated surface of the active material. Function j_{C}(T, CCP_{c}, ΔDOD, I) considers cracking in the active material itself. The positive electrode capacity Q_{c} is represented as a function of the battery temperature T, the positive-electrode closed circuit potential CCP_{c}, the change amount ΔDOD (or pulverization function f(t, ΔDOD)), and the charge-discharge current value I.

[Math. 10]

Q_{c}=j_{A}(T,CCP_{c})×j_{B}(T,CCP_{c},ΔDOD,I)×j_{C}(T,CCP_{c},ΔDOD,I) (10)

The description below explains the calculation of the positive/negative electrode SOC misalignment capacity Q_{Li}. The positive/negative electrode SOC misalignment capacity Q_{Li} correlates with the consumption of lithium ions due to the formation of a coat (SEI: Solid Electrolyte Interface) at the negative and positive electrodes. The consumption of lithium ions due to coat formation is a chemical reaction. The positive/negative electrode SOC misalignment capacity Q_{Li} follows the Arrhenius law. The positive/negative electrode SOC misalignment capacity Q_{Li} can be expressed as a function of the battery temperature T.

The lithium ion consumption due to coat formation at the negative and positive electrodes is an oxidation-reduction reaction and therefore conforms to Tafel law. The positive/negative electrode SOC misalignment capacity Q_{Li} can be expressed as a function of the negative-electrode closed circuit potential CCPₐ and the positive-electrode closed circuit potential CCP_{c}.

As the secondary battery 22 is repeatedly charged and discharged, the active material of the electrodes (positive and negative) is repeatedly expanded and contracted, thus advancing cracking in the surface coat of the active material of the electrodes. Each electrode surface is eventually exposed from the cracks in the coat. A new coat is formed on the exposed surface, increasing the consumption of lithium ions. An increase in the change amount ΔDOD increases the degree of expansion and contraction of the active material. The positive/negative electrode SOC misalignment capacity Q_{Li} can be expressed as a function of the change amount ΔDOD.

At the electrodes as above, the active material repeatedly expands and contracts to crack the active material itself and decrease the diameter. Cracking of the active material itself includes factors to increase and decrease the positive/negative electrode SOC misalignment capacity Q_{Li}.

Cracking of the active material itself generates a new surface (no coat formed) on the active material. Then, lithium ions move more easily to the active material of each electrode, causing an increase in the positive/negative electrode SOC misalignment capacity Q_{Li}. When a new surface is formed on the active material, the coat formation is promoted on the new surface to consume lithium ions, causing a decrease in the positive/negative electrode SOC misalignment capacity Q_{Li}.

In consideration of the foregoing, the positive/negative electrode SOC misalignment capacity Q_{Li} can be expressed by an equation including a pulverization function f(t, ΔDOD), that is, a function of the variation ΔDOD, based on the theory similar to that of the negative electrode resistance Rₐ and the positive electrode resistance R_{c}.

Cracking of the active material itself of the electrodes also depends on the charge-discharge current value I. The current tends to flow intensively through a low-resistance part of the active material according to an increase in the charge-discharge current value I. There may occur a difference in the degree of expansion and contraction depending on parts of the active material. Strain easily occurs in the active material, causing cracks in the active material itself. Cracking of the electrodes' active material itself can be expressed as a function of the charge-discharge current value I or a C-rate function correlated with the charge-discharge current value I.

The positive/negative electrode SOC misalignment capacity Q_{Li} is expressed by equation (11) through the use of functions k_{A}(T, CCPₐ), k_{B}(T, CCPₐ, ΔDOD, I), k_{C}(T, CCPₐ, ΔDOD, I), I_{A}(T, CCP_{c}), I_{B}(T, CCP_{c}, ΔDOD, I), and I_{C}(T, CCP_{c}, ΔDOD, I).

The function k_{A}(T, CCPₐ) considers the formation of a coat on the surface of the negative electrode's active material. The function k_{B}(T, CCPₐ, ΔDOD, I) considers the cracking of the coat formed on the surface of the negative electrode's active material. The function k_{C}(T, CCPₐ, ΔDOD, I) considers the cracking of the negative electrode's active material itself.

The function I_{A}(T,CCP_{c}) considers the formation of a coat on the surface of the positive electrode's active material. The function I_{B}(T, CCP_{c}, ΔDOD, I) considers the cracking of the coat formed on the surface of the positive electrode's active material. The function I_{C}(T, CCP_{c}, ΔDOD, I) considers the cracking of the positive electrode's active material itself.

[Math. 11]

Q_{Li}=k_{A}(T,CCPₐ)×k_{B}(T,CCPₐ,ΔDOD,I)×k_{C}(T,CCPₐ,ΔDOD,I) +I_{A}(T,CCP_{c})×I_{B}(T,CCP_{c},ΔDOD,I)×I_{C}(T,CCP_{c},ΔDOD,I) (11)

As above, the positive/negative electrode SOC misalignment capacity Q_{Li} can be expressed as a function of the battery temperature T, the negative-electrode closed circuit potential CCPₐ, the positive-electrode closed circuit potential CCP_{c}, the change amount ΔDOD, and the charge-discharge current value I.

In step S19, the degradation suppression system 1 acquires the battery capacity QB by using the negative electrode capacity Qₐ, the positive electrode capacity Q_{c}, and the positive/negative electrode SOC misalignment capacity Q_{Li} calculated in step S18. Specifically, the degradation suppression system 1 determines that the battery capacity Q_{B} of the secondary battery 22 is equal to the smallest one of the negative electrode capacity Qₐ, the positive electrode capacity Q_{c}, and the positive/negative electrode SOC misalignment capacity Q_{Li} of the secondary battery 22. The degradation suppression system 1 implements Q_{B}=min(Qₐ, Q_{c}, Q_{Li}).

As described above, the negative electrode capacity Qₐ corresponds to the number of negative electrode sites capable of lithium ion insertion. The positive electrode capacity Q_{c} corresponds to the number of positive electrode sites capable of lithium ion insertion. The positive/negative electrode SOC misalignment capacity Q_{Li} corresponds to the number of lithium ions movable between the positive electrode and the negative electrode as well as the ease of movement of the entire lithium ion. The smallest one of the negative electrode capacity Qₐ, the positive electrode capacity Q_{c}, and the positive/negative electrode SOC misalignment capacity Q_{Li} corresponds to the battery capacity Q_{B} of the secondary battery 22.

In step S19, the degradation suppression system 1 finds the battery resistance RB, that is, the resistance value of the entire secondary battery 22, through the use of the negative electrode resistance Rₐ and the positive electrode resistance R_{c}. Specifically, the degradation suppression system 1 determines that the sum of the components (negative electrode resistance Rₐ and positive electrode resistance R_{c}) configuring the secondary battery 22 is the resistance value of the entire secondary battery 22. The degradation suppression system 1 implements R_{B}=Rₐ+R_{c}.

As above, the process calculates the negative electrode resistance Rₐ, the positive electrode resistance R_{c}, the negative electrode capacity Qₐ, the positive electrode capacity Q_{c}, the positive/negative electrode SOC misalignment capacity Q_{Li}, the battery capacity Q_{B}, and the battery resistance R_{B} of the secondary batteries 22 at present. The degradation suppression system 1 calculates the element degradation states SOHQₐe, SOHQₐe, SOHQ_{Li}e, SOHRₐe, and SOHRₐe by using the calculated positive electrode capacity Q_{C}, for example.

For example, the element degradation state SOHQₐe is calculated by finding the ratio of the negative electrode capacity Qₐ of the present secondary battery 22 to the negative electrode capacity Qₐ of the initial secondary battery 22. The element degradation state SOHQₐe is calculated by finding the ratio of the positive electrode capacity Q_{c} of the present secondary battery 22 to the positive electrode capacity Q_{c} of the initial secondary battery 22. The element degradation state SOHQ_{Li}e is calculated by finding the ratio of the positive/negative electrode SOC misalignment capacity Q_{Li} of the present secondary battery 22 to the positive/negative electrode SOC misalignment capacity Q_{Li} of the initial secondary battery 22.

The element degradation state SOH Rae is calculated by finding the ratio of the negative electrode resistance Rₐ of the present secondary battery 22 to the negative electrode resistance Rₐ of the initial secondary battery 22. The element degradation state SOHRₐe is calculated by finding the ratio of the positive electrode resistance R_{c} of the present secondary battery 22 to the positive electrode resistance R_{c} of the initial secondary battery 22.

The degradation state of each component of the secondary battery 22 can be highly accurately predicted by calculating the degradation state of each component of the secondary battery 22 in consideration of the degradation factors of the components.

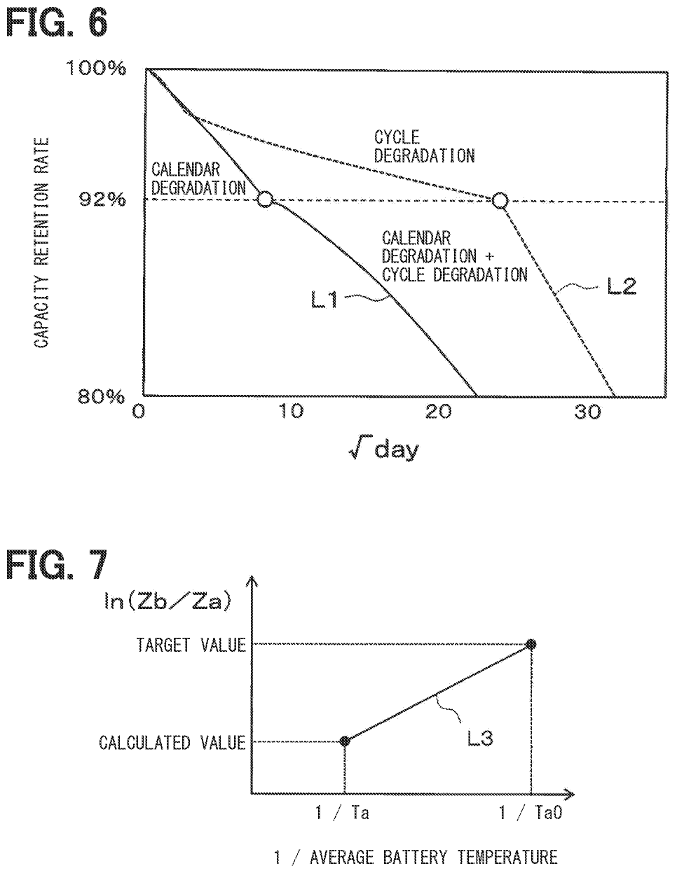

This will be explained by using specific examples and by reference to FIG. 6. As a specific example, two secondary batteries 22 of the same type, hereinafter referred to as a first battery and a second battery for convenience, are used to provide simulation results regarding the impact of differences in degradation factors on the advancement of future degradation.

The first battery and the second battery represent secondary batteries of the same type. Regarding the graph illustrated in FIG. 6, the horizontal axis indicates the square root of the number of days, and the vertical axis indicates the capacity retention rate of the secondary battery 22. The capacity retention rate of the secondary battery 22 at a predetermined time represents the ratio of the capacity of the secondary battery 22 at a predetermined time to the capacity of the secondary battery 22 in the initial state.

In FIG. 6, line L1 shows experimental results on the first battery, and line L2 shows experimental results on the second battery. The results for each of the first and second batteries illustrated in FIG. 6 reveal that the positive/negative electrode SOC misalignment capacity Q_{Li} is the smallest one of the negative electrode capacity Qₐ, the positive electrode capacity Q_{c}, and the positive/negative electrode SOC misalignment capacity Q_{Li}. The experimental results of the first battery and the second battery show that battery capacity Q_{B}=positive/negative electrode SOC misalignment capacity Q_{Li}.

The secondary battery 22 flowing a large current for automobile driving, for example, is often used only in a region that minimizes the positive/negative electrode SOC misalignment capacity Q_{Li} out of the negative electrode capacity Qₐ, the positive electrode capacity Q_{c}, and the positive/negative electrode SOC misalignment capacity Q_{Li} of the secondary battery 22. The secondary battery 22 flowing a large current often causes the battery capacity Q_{B} to be equal to the positive/negative electrode SOC misalignment capacity Q_{Li}.

The example in FIG. 6 forces the first battery to decrease the capacity retention rate from 100% to 92% under the condition that the first battery undergoes calendar degradation in an environment of 45° C. In this case, decreases in the capacity of the first battery indicate 7.2% due to coat formation on each electrode, 0.4% due to cracking of a coat formed on the surface of each electrode's active material, and 0.4% due to cracking of each electrode's active material itself.

The example in FIG. 6 forces the second battery to decrease the capacity retention rate from 100% to 92% under the condition that the second battery undergoes cycle degradation in an environment of 45° C. In this case, decreases in the capacity of the second battery indicate 4.0% due to coat formation on each electrode, 1.6% due to cracking of a coat formed on the surface of each electrode's active material, and 2.4% due to cracking of each electrode's active material itself.

It can be seen that the first battery and the second battery use different values for the functions constituting equation (11) for positive/negative electrode SOC misalignment capacity Q_{Li} depending on usage situations so far even if the first battery and the second battery use the same capacity retention rate and positive/negative electrode SOC misalignment capacity Q_{Li}.

The first battery and the second battery at a capacity retention rate of 92% were degraded under the same conditions by combining the cycle degradation and the calendar degradation. As illustrated in FIG. 6, the slope of line L2 indicating the degradation state of the second battery is greater than the slope of line L1 indicating the degradation state of the first battery in the region where the capacity retention rate is 92% or less. Under this condition, it can be seen that the second battery initially subject to the cycle degradation degrades earlier than the first battery initially subject to the calendar degradation.

It can be seen that even the secondary batteries 22 at the same capacity retention rate differently degrade afterward depending on the usage states of the secondary batteries 22 so far. The highly accurate battery capacity Q_{B} can be calculated by calculating the positive/negative electrode SOC misalignment capacity Q_{Li} based on the function considering coat formation on each electrode, the function considering cracking of the coat formed on the surface of each electrode's active material, and the function considering cracking of each electrode's active material itself. The same applies to a case where the battery capacity Q_{B} corresponds to the negative electrode capacity Qₐ or the positive electrode capacity Q_{c}.

The negative electrode resistance Rₐ and the positive electrode resistance R_{c} are also calculated in consideration of the degradation factors. The negative electrode resistance Rₐ and the positive electrode resistance R_{c} can also be highly precisely calculated based on the logic similar to that for the above-mentioned battery capacity Q_{B}.

Returning to FIG. 2, the description below explains the process after step S5. In step S5, the process extracts multiple degradation factors causing the battery state of the secondary battery 22 mounted on the vehicle V. The difference between the initial state of the secondary battery 22 and the current state of the secondary battery 22 is hereinafter referred to as a total degradation amount Z.

The total degradation amount Z includes calendar degradation amount Za resulting from the calendar degradation, cycle degradation amount Zb resulting from the cycle degradation, and degradation amount Zc resulting from the other degradation factors. The total degradation amount Z is then expressed by equation (12) below.

[Math. 12]

Z=Za+Zb+Zc (12)

The calendar degradation amount Za represents the degradation amount of the secondary battery 22 caused by the calendar degradation. The calendar degradation advances with time, regardless of the energization of the secondary battery 22, and tends to further advance corresponding to an increase in the battery temperature T of the secondary battery 22. The calendar degradation is considered to advance due to the formation of a coat on the surface of the active material.

As above, the coat is formed as a result of oxidation-reduction decomposition of the electrolyte and its additives of the secondary battery 22 according to the Arrhenius law. The calendar degradation amount Za can be represented as a function of the battery temperature T. The coat formation is also caused by oxidation-reduction and therefore follows the Tafel law. The calendar degradation amount Za can be expressed as a function of the closed circuit potential CCP. The calendar degradation amount Za can be found according to equation (13) using the functions in consideration of the coat formation in equations (9) to (11) above.

[Math. 13]

Za=f(i_{A}(T,CCPₐ),j_{A}(T,CCP_{c}),k_{A}(T,CCPₐ),I_{A}(T,CCP_{c})) (13)

The cycle degradation amount Zb represents the degradation amount of the secondary battery 22 caused by the cycle degradation. The cycle degradation advances due to the energization of the secondary battery 22 and tends to further advance due to the energization of the secondary battery 22 at a low battery temperature. The cycle degradation is caused by the expansion and contraction of each electrode, for example, and is considered to advance due cracking of a coat formed on the surface of the active material.

As above, cracking in the surface coat advances due to repeated expansion and contraction of the active material as the secondary battery 22 is repeatedly charged and discharged. The amount of coating increases as a new coat is formed on the plane exposed from the crack, further advancing the degradation. The increase in the amount of change ΔDOD increases the degree of expansion and contraction of the active material. The cycle degradation amount Zb can be expressed as a function of the change amount ΔDOD. The cycle degradation amount Zb can be found according to formula (14) using the functions in consideration of cracking of the coat formed on the surface of the active material in formulas (9) to (11) above.

[Math. 14]

Zb=f(i_{B}(T,CCPₐ,ΔDOD,I),j_{B}(T,CCP_{c},ΔDOD,I),k_{B}(T,CCPₐ,ΔDOD,I),I_{B}(T,CCP_{c},ΔDOD,I)) (14)

Equations (13) and (14) can be used to find the calendar degradation amount Za and the cycle degradation amount Zb in the total degradation amount Z of the secondary battery 22 at present. It is possible to evaluate which of the degradations, calendar or cycle, strongly influences the secondary battery degradation 22 at present. As above, the calendar degradation is caused by the formation of a coat on the surface of the active material. The cycle degradation is caused by cracking of the coat formed on the surface of the active material.

The degradation suppression system 1 proceeds to step S6 to acquire the optimum average temperature TaO, a target value for the subsequent temperature adjustment of the secondary battery 22, based on the configuration of the degradation factors in the total degradation amount Z calculated in step S5. The optimum average temperature TaO is the target value for the average battery temperature Ta, which is determined so that the future degradation amount of the secondary battery 22 is minimized to inhibit the secondary battery 22 from further degrading.

Specifically, the degradation suppression system 1 uses the calendar degradation amount Za and the cycle degradation amount Zb calculated in step S5 to calculate a composition ratio Zb/Za of the degradation factors. The composition ratio Zb/Za is calculated through the use of the calendar degradation amount Za and the cycle degradation amount Zb, both calculated through the use of the battery load history, and thus follows the degradation characteristics, identified by the battery load history, of the secondary battery 22.

The description below explains the relationship between the natural logarithm of the composition ratio Zb/Za and the reciprocal of the average battery temperature Ta by reference to FIG. 7. As above, a calculated value for the natural logarithm of the composition ratio Zb/Za follows the degradation characteristics, identified by the battery load history, of the secondary battery 22. In FIG. 7, a point indicating the current degradation state of the secondary battery 22 is settled based on the calculated value for the natural logarithm of the composition ratio Zb/Za and the reciprocal of the average battery temperature Ta calculated in step S2.

Line L3 passes through known points related to the calculated values of the natural logarithm for the composition ratio Zb/Za and follows the degradation characteristics, specified by battery load history, of the secondary battery 22. The slope of line L3 indicates a constant determined by the specifications or models, for example, of the secondary battery 22.

A point on line L3 can specify a predicted value of the future degradation amount of the secondary battery 22 on the premise of the current degradation state of the secondary battery 22. In other words, the point on line L3 can specify a point corresponding to the minimum predicted value for the future degradation amount of the secondary battery 22.

Regarding the relationship between the natural logarithm of the composition ratio Zb/Za and the degradation amount of the secondary battery 22, it is already known that the minimized degradation amount of the secondary battery 22 indicates the composition ratio Zb/Za specified from the specifications or models, for example, of the secondary battery 22. The composition ratio Zb/Za specified from the specifications, for example, of the secondary battery 22 is a target value for the composition ratio Zb/Za determined to minimize the degradation amount of the secondary battery 22 and exemplifies the target composition ratio.

It is possible to specify a reciprocal of the average battery temperature Ta corresponding to the minimized degradation of the secondary battery 22 based on the composition ratio Zb/Za and straight line L3. The composition ratio Zb/Za is specified from the specifications of the secondary battery 22. Straight line L3 follows the degradation characteristics of the secondary battery 22. The average battery temperature Ta corresponding to the minimized degradation of the secondary battery 22 is defined as the optimum average temperature TaO, that is, a target value of the average battery temperature Ta. The optimum average temperature TaO corresponds to an example of the optimum battery temperature.

The value for the composition ratio Zb/Za corresponding to the minimized degradation amount of the secondary battery 22 and the value for the slope of line L3 are stored in the BMU 21 in association with the specifications and models of the secondary battery 22, for example. In step S6, the degradation suppression system 1 corrects the value of the composition ratio Zb/Za corresponding to the minimized degradation amount of the secondary battery 22 based on the frequency of DOD included in the battery load history acquired in step S1.

Specifically, the degradation suppression system 1 performs the correction so that the value of the composition ratio Zb/Za corresponding to the minimized degradation amount of the secondary battery 22 increases as the frequency of DOD increases. It is possible to reflect the magnitude of stress due to DOD on the degradation of the secondary battery 22. The optimum average temperature TaO can be defined as a more appropriate optimum battery temperature.

In step S7, the degradation suppression system 1 updates the mode of temperature adjustment control over the secondary battery 22 by using the average battery temperature Ta calculated in step S2 and the optimum average temperature TaO calculated in step S6, to minimize future degradation of the secondary battery 22.

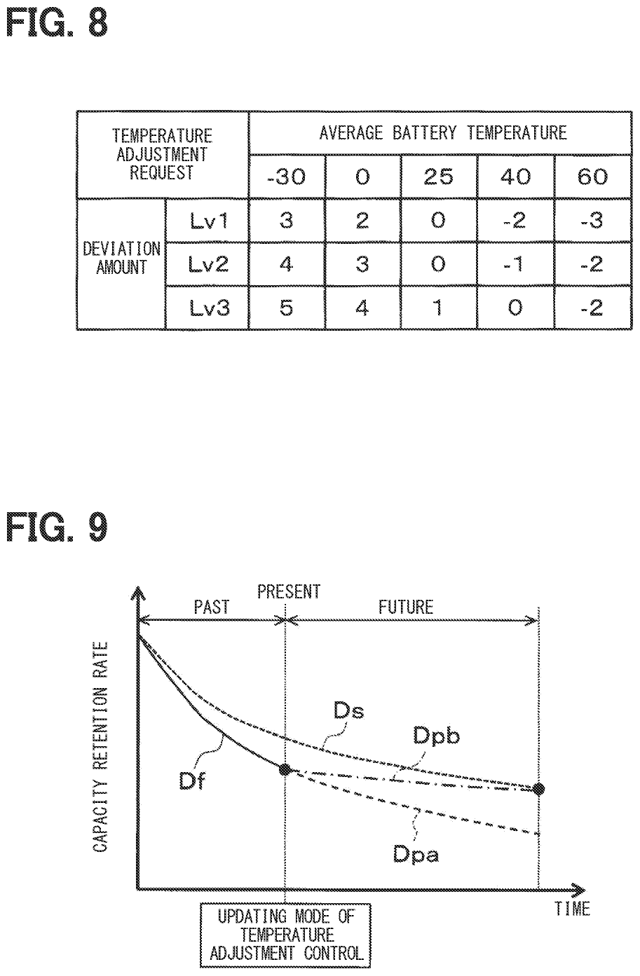

The degradation suppression system 1 references a temperature adjustment request map when controlling the refrigeration cycle device 31, that is, a temperature adjustment unit. As illustrated in FIG. 8, the temperature adjustment request map is configured to output a temperature adjustment start temperature and a temperature adjustment amount by using arguments such as the deviation rate between the optimum average temperature TaO and the average battery temperature Ta and the battery temperature T of the secondary battery 22.

The deviation rate is determined by a difference between the average battery temperature Ta calculated in step S2 and the optimum average temperature TaO calculated in step S6. The deviation rates are divided into Lv1 through Lv3 corresponding to numerical ranges to which a difference value belongs.

The deviation rates correspond to Lv1, Lv2, and Lv3 in ascending order of difference values. Instead of Lv1 to Lv3 as an example of the deviation rate division, it may be favorable to adopt other implementations capable of indicating a difference between the average battery temperature Ta and the optimum average temperature TaO.

The degradation suppression system 1 updates the output values defined in the temperature adjustment request map according to the result of the comparison between the average battery temperature Ta and the optimum average temperature TaO in terms of which is larger or smaller. For example, suppose the average battery temperature Ta is lower than the optimum average temperature TaO and it is necessary to suppress the future deterioration amount of the secondary battery 22. Then, the temperature adjustment control over the secondary battery 22 needs to increase the frequency of heating control over the secondary battery 22 or increase the target temperature, for example. The degradation suppression system 1 updates the contents of the temperature adjustment request map to increase the average battery temperature Ta acquired for future use of the secondary battery 22.

For example, suppose the average battery temperature Ta is higher than the optimum average temperature TaO and it is necessary to suppress the future deterioration amount of the secondary battery 22. Then, the temperature adjustment control over the secondary battery 22 needs to increase the frequency of cooling control over the secondary battery 22 or decrease the target temperature, for example. The degradation suppression system 1 updates the contents of the temperature adjustment request map to decrease the average battery temperature Ta acquired for future use of the secondary battery 22.

In step S8, the degradation suppression system 1 controls operations of the refrigeration cycle device 31 to control the temperature adjustment of the secondary battery 22 according to the temperature adjustment request map updated in step S7. The refrigeration cycle device 31 controls the temperature adjustment so that the future average battery temperature Ta approximates the optimum average temperature TaO.

As a result, the degradation suppression system 1 can control the temperature adjustment of the secondary battery 22 and suppress the future degradation amount to the minimum in a manner according to the configuration of degradation factors of the current degradation of the secondary battery 22.

The description below explains the effects of the degradation suppression system 1 according to the first embodiment by reference to FIG. 9. In FIG. 9, line Df indicates usage-dependent changes in the capacity retention rate of the secondary battery 22 up to the present time. Line Ds indicates an assumed value of the change in the capacity retention rate defined at the design stage of the secondary battery 22.

Referring to the present time in FIG. 9, the current capacity retention rate of the secondary battery 22 indicated by line Df shows a lower value than the assumed capacity retention rate indicated by line Ds. The present difference in capacity retention rates is caused by how the secondary battery 22 is used and correlates with the difference in the configurations of degradation factors.

Referring to the future in FIG. 9, line Dpa shows changes in the capacity retention rate when the secondary battery 22 is used as is without providing the degradation suppression control such as updating the mode of temperature adjustment control. Line Dpb shows changes in the capacity retention rate of the secondary battery 22 when the degradation suppression control is provided based on the control program according to the first embodiment.

As above, the degradation suppression system 1 according to the first embodiment performs control based on the flowchart illustrated in FIG. 2 and thereby performs the temperature adjustment control over the secondary battery 22 in a mode corresponding to the configuration of degradation factors of the current degradation of the secondary battery 22. The capacity retention rate of the secondary battery 22 in the future changes as indicated by line Dpb, making it possible to suppress the degradation of the secondary battery 22. In other words, the degradation suppression system 1 can perform the degradation suppression control to approximate the actual degradation state indicated by line Dpa to the assumed degradation state indicated by line Ds.

As above, the degradation suppression system 1 according to the first embodiment provides control based on the flowchart illustrated in FIG. 2, thereby making it possible to perform the degradation suppression control according to the configuration of the calendar degradation and the cycle degradation as the current degradation of the secondary battery 22.

The control contents can reflect the details of degradations such as the configuration of calendar degradation and cycle degradation in addition to the current degradation amount of the secondary battery 22. It is possible to appropriately suppress future degradation of the secondary battery 22.

In step S6, the degradation suppression system 1 predicts the future degradation amount of the secondary battery 22 and determines the optimum average temperature TaO so that the future degradation amount is minimized. A tendency toward the future period of the temperature adjustment of the secondary battery 22 can reflect the configuration of degradation factors and the prediction of a future degradation amount. It is possible to adjust the temperature of the secondary battery 22 more appropriately.

In steps S7 and S8, the degradation suppression system 1 updates the future mode of the temperature adjustment control so that the average battery temperature Ta approximates the optimum average temperature TaO calculated in step S6. The optimum average temperature TaO and the average battery temperature Ta provide average values of the battery temperature T during a predetermined period.

The degradation suppression system 1 can appropriately change the frequency of heating and cooling of the secondary battery 22 based on the refrigeration cycle device 31 and the target value of the battery temperature T and can more reliably suppress future degradation of the secondary battery 22.

As illustrated in FIG. 7, the degradation suppression system 1 calculates the optimum average temperature TaO by using the average battery temperature Ta, the calculated value of the composition ratio Zb/Za, and the target value of the composition ratio Zb/Za corresponding to the minimum degradation of the secondary battery 22.

It is possible to change how often the refrigeration cycle device 31 heats and cools the secondary battery 22 and change the target value of the battery temperature T, for example, based on a long-term perspective. Future degradation of the secondary battery 22 can be suppressed more reliably.

In step S7, when updating the temperature adjustment control mode, the degradation suppression system 1 updates numerical values in the temperature adjustment request map so that the average battery temperature Ta approximates the optimum average temperature TaO. As illustrated in FIG. 8, the temperature adjustment request map is divided into multiple levels according to the deviation amount between the average battery temperature Ta and the optimum average temperature TaO. The deviation amount levels are assigned corresponding output values.

In step S7, the output values in the temperature adjustment request map are updated, making it possible to control operations of the refrigeration cycle device 31 according to the deviation amount between the average battery temperature Ta and the optimum average temperature TaO. The average battery temperature Ta approximates the optimum average temperature TaO, making it possible to suppress the degradation of the secondary battery 22.

As illustrated in FIG. 8, the current battery temperature T is defined as an argument in the temperature adjustment request map that is configured to output a temperature adjustment request value defined from the battery temperature T and the deviation amount.

The temperature adjustment of the secondary battery 22 using the refrigeration cycle device 31 can reflect the deviation rate based on the battery temperature T and a long-term perspective. It is possible to suppress the deterioration of the secondary battery 22 by more reliably approximating the average battery temperature Ta to the optimum average temperature TaO.

In step S6, when calculating the optimum average temperature TaO, the degradation suppression system 1 corrects the value of the composition ratio Zb/Za corresponding to the minimum degradation amount of the secondary battery 22 based on the frequency of DOD included in the battery load history. Specifically, the degradation suppression system 1 performs the correction so that the value of the composition ratio Zb/Za corresponding to the minimized degradation amount of the secondary battery 22 increases as the frequency of DOD increases.

The calculation of the optimum average temperature TaO can reflect the magnitude of stress due to DOD on the degradation of the secondary battery 22. It is possible to settle a more appropriate optimum average temperature TaO and suppress the degradation of the secondary battery 22.

### Second Embodiment

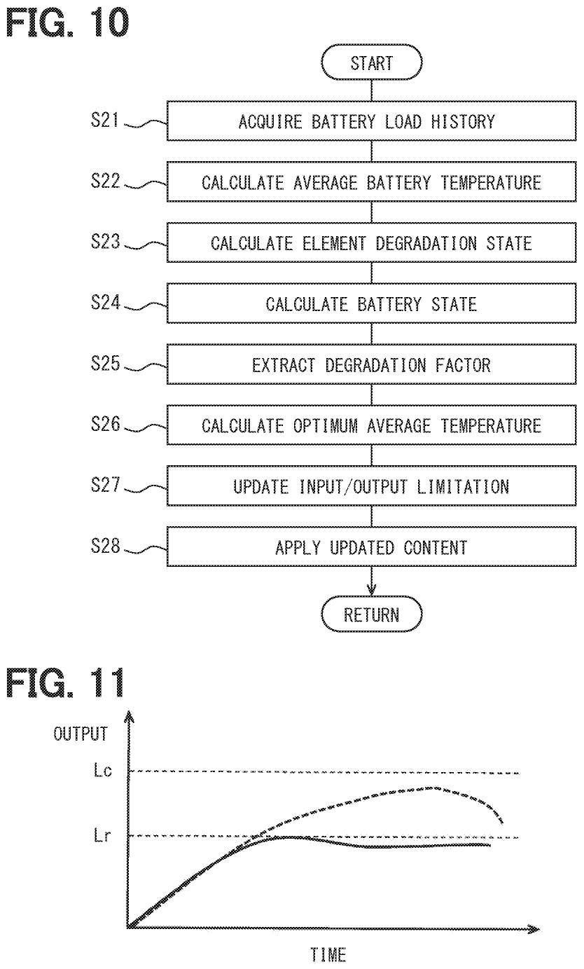

The description below explains the second embodiment that differs from the above-described embodiment by reference to FIGS. 10 to 12. The second embodiment partially differs from the above-described embodiment in the contents of the degradation suppression process. The basic configuration of the degradation suppression system 1 and the others are similar to those of the above-described embodiment and a repetitive description is omitted for simplicity.

The degradation suppression system 1 according to the second embodiment performs the degradation suppression process based on the flowchart illustrated in FIG. 10. The processing contents in steps S21 to S26 of the degradation suppression process according to the second embodiment are similar to those in steps S1 to S6 according to the first embodiment and a repetitive description is omitted for simplicity.

In step S27, the process updates an input/output limitation, as a limitation mode, defined for the secondary battery 22 so that the average battery temperature Ta calculated in step S22 approximates the optimum average temperature TaO calculated in step S26.

Generally, the secondary battery 22 generates heat according to inputs and outputs. The battery temperature T of the secondary battery 22 can be adjusted by changing the limit value of the input/output limitation. The limit value is changed in the input/output limitation to appropriately adjust the battery temperature T of the secondary battery 22. Thereby, it is possible to approximate the average battery temperature Ta for a predetermined period to the optimum average temperature TaO.

Specifically, in step S27, the degradation suppression system 1 changes the presence or absence of the input/output limitation on the secondary battery 22 according to the result of the comparison between the average battery temperature Ta and the optimum average temperature TaO. The average battery temperature Ta may be higher than the optimum average temperature TaO. Then, the degradation suppression system 1 decreases the limit value of the input/output limitation on the secondary battery 22 or narrows an allowable range of the input/output limitation. The average battery temperature Ta may be lower than the optimum average temperature TaO. Then, the degradation suppression system 1 increases the limit value of the input/output limitation on the secondary battery 22 or expands an allowable range of the input/output limitation. In this case, no limit is set to the input/output of the secondary battery 22.

The degradation suppression system 1 proceeds to step S28 and activates the mode of the input/output limitation, updated in step S27, on the secondary battery 22. The amount of heat generation and the battery temperature T during input/output from the secondary battery 22 will be adjusted. The degradation suppression system 1 can approximate the average battery temperature Ta to the optimum average temperature TaO and suppress degradation of the secondary battery 22.

The above-described example decreases the limit value for the input/output limitation on the secondary battery 22 when the average battery temperature Ta is higher than the optimum average temperature TaO. The amount of heat generated by the secondary battery 22 during input/output decreases. After the input/output limitation is updated, the average battery temperature Ta decreases and approximates the optimum average temperature TaO. The degradation suppression system 1 can then appropriately suppress the degradation of the secondary battery 22 after the update.

When the average battery temperature Ta is lower than the optimum average temperature TaO, the degradation suppression system 1 increases the limit value of the input/output limitation specified for the secondary battery 22. After the input/output limitation is updated, the average battery temperature Ta increases and approximates the optimum average temperature TaO. The degradation suppression system 1 can then appropriately suppress the degradation of the secondary battery 22 after the update.

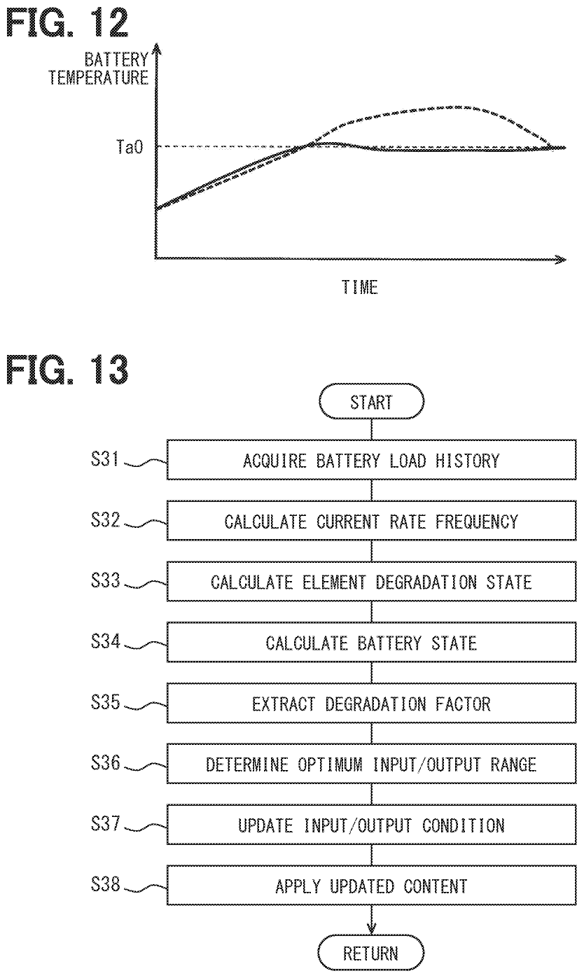

The description below explains the effects of the degradation suppression system 1 according to the second embodiment by reference to FIGS. 11 and 12 through the use of a specific example where the average battery temperature Ta is higher than the optimum average temperature TaO. In FIGS. 11 and 12, the dashed line indicates the input/output limitation state before the update and the solid line indicates the input/output limitation state after the update.

In step S27 according to this example, the average battery temperature Ta is higher than the optimum average temperature TaO. The degradation suppression system 1 tightens the input/output limitation by decreasing the limit value of the input/output limitation specified for the secondary battery 22. Specifically, the degradation suppression system 1 updates a pre-update limit value Lc to a post-update limit value Lr. The pre-update limit value Lc provides the output limit currently specified for the secondary battery 22. The post-update limit value Lr represents a value smaller than the pre-update limit value Lc.

In step S28, the pre-update limit value Lc is changed to the post-update limit value Lr to apply a stricter input/output limitation. The degradation suppression system 1 then provides input/output control over the secondary battery 22 according to the post-update limit value Lr. As illustrated in FIG. 11, the output from the secondary battery 22 is limited according to the post-update limit value Lr and is prevented from exceeding the post-update limit value Lr, unlike the input/output limitation before the update.

A change to the post-update limit value Lr causes the secondary battery 22 to output less frequently. As illustrated in FIG. 12, the battery temperature T of the secondary battery 22 becomes lower than the reference value Ts determined by the optimum average temperature TaO. The reference value Ts is defined so that the average battery temperature Ta approximates the optimum average temperature TaO. The degradation suppression system 1 can suppress the degradation of the secondary battery 22 by updating the input/output limitation on the secondary battery 22 to the post-update limit value Lr.

As above, the degradation suppression system 1 according to the second embodiment can reflect the details of the degradation, such as the configuration of calendar degradation and cycle degradation, on the control contents in addition to the degradation amount of the secondary battery 22 at present. The degradation suppression system 1 can appropriately suppress future degradation of the secondary battery 22 according to the detailed mode of degradation on the secondary battery 22.

In step S26, like step S6, the optimum average temperature TaO is determined so that the future degradation amount of the secondary battery 22 is estimated and minimized. It is possible to reflect the configuration of degradation factors and the estimation of future degradation amount on the tendency of a future period for the temperature adjustment of the secondary battery 22. The input/output limitation on the secondary battery 22 can be updated more appropriately.

In steps S27 and S28, the degradation suppression system 1 updates the mode of the input/output limitation on the secondary batteries 22 in the future so that the average battery temperature Ta approximates the optimum average temperature TaO calculated in step S26. The degradation suppression system 1 can more reliably suppress future degradation of the secondary battery 22 by appropriately controlling the amount of heat generated from the secondary battery 22 during input/output.

### Third Embodiment

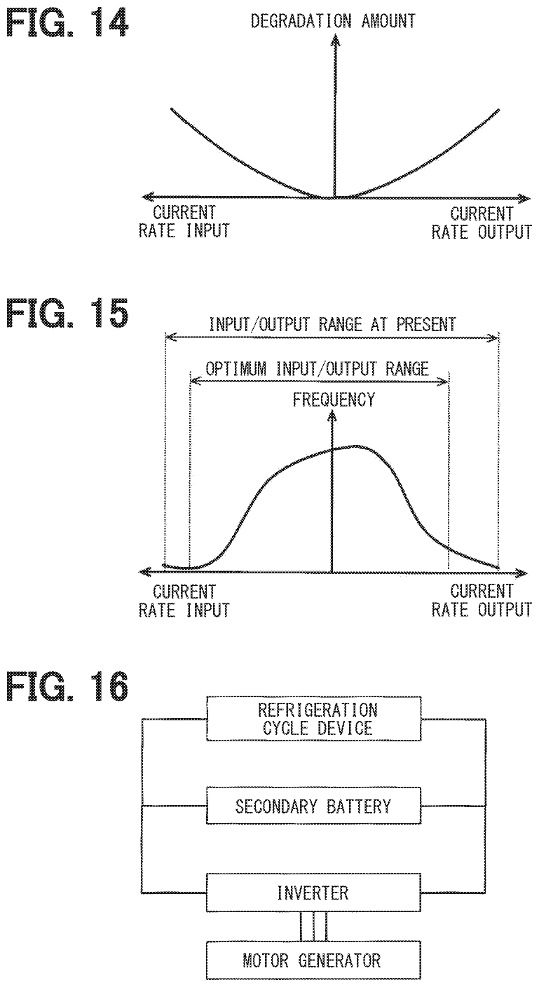

The description below explains the third embodiment that differs from the above-described embodiments by reference to FIGS. 13 and 14. The third embodiment partially differs from the above-described embodiments in the contents of the degradation suppression process. The basic configuration of the degradation suppression system 1 and the others are similar to those of the above-described embodiment and a repetitive description is omitted for simplicity.

The degradation suppression system 1 according to the third embodiment performs the degradation suppression process based on the flowchart illustrated in FIG. 13. The degradation suppression system 1 according to the third embodiment optimizes an input/output range defined for the secondary battery 22 as an input/output limitation mode of the secondary battery 22. In step S31 of the degradation suppression process according to the third embodiment, the degradation suppression system 1 acquires the battery load history similarly to the above-described embodiments.

In step S32, the process calculates the current rate frequency by using the battery load history acquired in step S31. Specifically, the current rate and its frequency are calculated through the use of the charge-discharge current value I included in the battery load history as usage history information.

The processing contents of steps S33 through S35 are similar to those of steps S3 through S5 in the above-described embodiments. A description of the processing contents of steps S33 through S35 is omitted for simplicity.

In step S36, the degradation suppression system 1 determines an optimum input/output range for the secondary battery 22 as an optimum input/output condition that minimizes the future degradation amount of the secondary battery 22. According to the third embodiment, the optimum input/output range for the secondary battery 22 is determined to be optimal based on the relationship between the stress (such as responsiveness to acceleration) on a user of the vehicle V and the input/output current value of the secondary battery 22 to be limited. The degradation suppression system 1 adjusts and determines the optimum input/output range to minimize the future degradation amount of the secondary battery 22, by using the current rate frequency calculated from the battery load history and the composition ratio of the cycle degradation amount Zb to the calendar degradation amount Za extracted in step S35, for example.

In step S38, the degradation suppression system 1 applies the optimum input/output range for the secondary battery 22 as the optimum input condition updated in step S27. Inputs/outputs from the secondary battery 22 will occur within the optimum input/output range. The degradation suppression system 1 can appropriately suppress future degradation of the secondary battery 22 in the mode that reflects the degradation amount and the configuration of degradation factors relating to the secondary battery 22 at present.

The description below explains the effects of the degradation suppression system 1 according to the third embodiment by reference to FIGS. 14 and 15.

As illustrated in FIG. 14, the degradation amount relating to the secondary battery 22 tends to increase as the current rate increases during input/output from the secondary battery 22. The degradation amount relating to the secondary battery 22 also tends to increase corresponding to an increase in the value of DOD or the average SOC, though not illustrated.

According to the third embodiment, as illustrated in FIG. 15, the degradation suppression system 1 appropriately adjusts the input/output range of the secondary battery 22 based on the degradation amount and the configuration of degradation factors relating to the secondary battery 22. The degradation suppression system 1 can appropriately suppress future secondary battery degradation 22 by adjusting the input/output range for the secondary battery 22 to the optimum input/output range.

The degradation suppression system 1 according to the third embodiment defines the optimum input/output range as the optimum input condition based on the degradation amount and the configuration of degradation factors relating to the secondary battery 22 so that the future degradation amount of the secondary battery 22 is minimized. The degradation suppression system 1 can suppress future degradation of the secondary battery 22 in an appropriate mode by applying the optimum input/output range.

Input to and output from the secondary battery 22 after the update are performed in the optimum input/output range defined as the optimum input/output condition. It is possible to appropriately suppress the degradation of the secondary battery 22 due to input and output.

The third embodiment uses the current rate frequency to define the optimum input/output range as the optimum input/output condition. However, the present disclosure is not limited thereto. As above, the degradation of the secondary battery 22 tends to greatly advance corresponding to an increased value of DOD or average SOC. For example, DOD or average SOC may be used to determine the optimum input/output condition.

### Fourth Embodiment

Next, the description below explains the fourth embodiment that differs from the above-described embodiments by reference to FIGS. The fourth embodiment differs from the above-described embodiments in the contents of steps S36 through S38 according to the third embodiment. The basic configuration of the degradation suppression system 1 and the others are similar to those of the above-described embodiment and a repetitive description is omitted for simplicity.

In step S36 according to the fourth embodiment, the process defines an input reference value and an output reference value for the secondary battery 22, as the optimum input/output condition corresponding to a minimum degradation amount of the secondary battery 22 in the future. The input reference value and the output reference value, an example of the limitation mode of the input/output limitation on the secondary battery 22, are smaller than the limit value of the input/output range and, unlike the limit value, does not provide the function of restricting the input/output over the range.

The input reference value and output reference value are determined to be optimal based on the relationship between the stress (such as responsiveness to acceleration) on a user of the vehicle V and the input/output current value of the secondary battery 22 to be limited. The degradation suppression system 1 adjusts and determines the input reference value and the output reference value to minimize the future degradation amount of the secondary battery 22, by using the current rate frequency and the composition ratio of the cycle degradation amount Zb to the calendar degradation amount Za extracted in step S35, for example.

In step S37, the degradation suppression system 1 applies the determined input reference value and output reference value to the input control and output control over the secondary battery 22. In step S38, the process controls the input and output of the secondary battery 22 by using the input reference value and the output reference value.

For example, suppose the supply power Pr is large and the input power Pi to the secondary battery 22 exceeds the input reference value. In this case, the degradation suppression system 1 appropriately consumes the power to consume part of the supply power Pr and thereby forces the input power Pi to the secondary battery 22 to correspond to the input reference value. Suppose the power consumption Pc is large and the output power of the secondary battery 22 exceeds the output reference value. In this case, the degradation suppression system 1 appropriately supplies the power to partially supplement the power consumption Pc and thereby forces the output voltage from the secondary battery 22 to correspond to the output reference value.

The secondary battery 22 can be freed from input/output over the input reference value and the output reference value. It is possible to suppress the degradation of the secondary battery 22 due to input/output. As above, the input reference value and the output reference value are determined in consideration of the degradation amount and the configuration of degradation factors relating to the secondary battery 22 at present. The degradation suppression system 1 can suppress the degradation in an appropriate mode to minimize future degradation of the secondary battery 22.

The description below explains the effects of the degradation suppression system 1 according to the fourth embodiment by reference to FIGS. 16 to 18. As illustrated in FIG. 16, the degradation suppression system 1 includes the secondary battery 22, the inverter 23, the motor generator 24, and the refrigeration cycle device 31.

The motor generator 24 and the inverter 23 supply regenerated power to the secondary battery 22, making it possible to store the regenerated electric power in the vehicle V. When air-conditioning the vehicle compartment, the vehicle V consumes power from the secondary battery 22 to operate the refrigeration cycle device 31.

Based on these configurations, the description below explains the effects of the degradation suppression system 1 according to the fourth through the use of specific examples. Specifically, in an example to be described, the regenerated power via the motor generator 24 and the inverter 23 is input as the supply power Pr to the secondary battery 22. FIG. 17 illustrates the state that provides no input reference value. Pi represents the input power practically input to the secondary battery 22.

Since no input reference value is defined in FIG. 17, the supply power Pr, regenerated via the motor generator 24, for example, is fully input as input power Pi to the secondary battery 22.

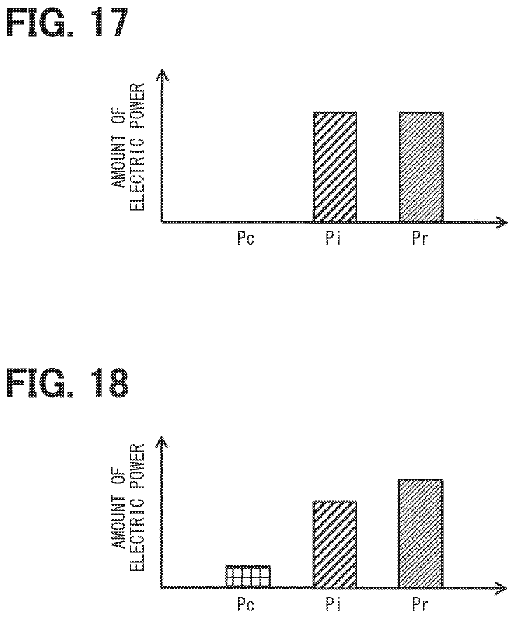

By reference to FIG. 18, the description below explains the case where the input reference value is provided for the degradation suppression system 1 according to the fourth embodiment, and the regenerative electric power via the motor generator 24, for example, exceeds the input reference value.

In this case, suppose the regenerative electric power is input as the supply power Pr to the secondary battery 22. Then, the secondary battery 22 is degraded more than expected, making it impossible to sufficiently suppress the degradation. To solve this, the degradation suppression system 1 balances the supply power Pr with the power consumption Pc so that the input power Pi does not exceed the input reference value.

Specifically, the degradation suppression system 1 operates the refrigeration cycle device 31 for vehicle compartment air-conditioning, partially consumes the supply power Pr, and thereby provides adjustment so that the input power Pi for the secondary battery 22 does not exceed the input reference value. According to the configuration above, it is possible to provide the input/output control over the secondary battery 22 based on the input reference value and the output reference value and appropriately suppress future degradation of the secondary battery 22.

The degradation suppression system 1 according to the fourth embodiment defines the input reference value and the output reference value as the optimum input condition based on the degradation amount and the configuration of degradation factors relating to the secondary battery 22 so that the future degradation amount of the secondary battery 22 is minimized. The degradation suppression system 1 can suppress future degradation of the secondary battery 22 in an appropriate mode by applying the input reference value and the output reference value.

Input to and output from the secondary battery 22 after the update are performed based on the optimum input/output range defined as the optimum input/output condition. It is possible to appropriately suppress the degradation of the secondary battery 22 due to input and output.

The fourth embodiment describes the power consumption Pc as power consumption due to operations of the refrigeration cycle device 31 and the supply power Pr as the regenerative electric power via the motor generator 24 and the inverter 23. However, the present disclosure is not limited thereto. The power consumption Pc can be applied to various devices as power consumption targets. The supply power Pr may represent the power supply from a power supply device outside the vehicle V.

### Fifth Embodiment

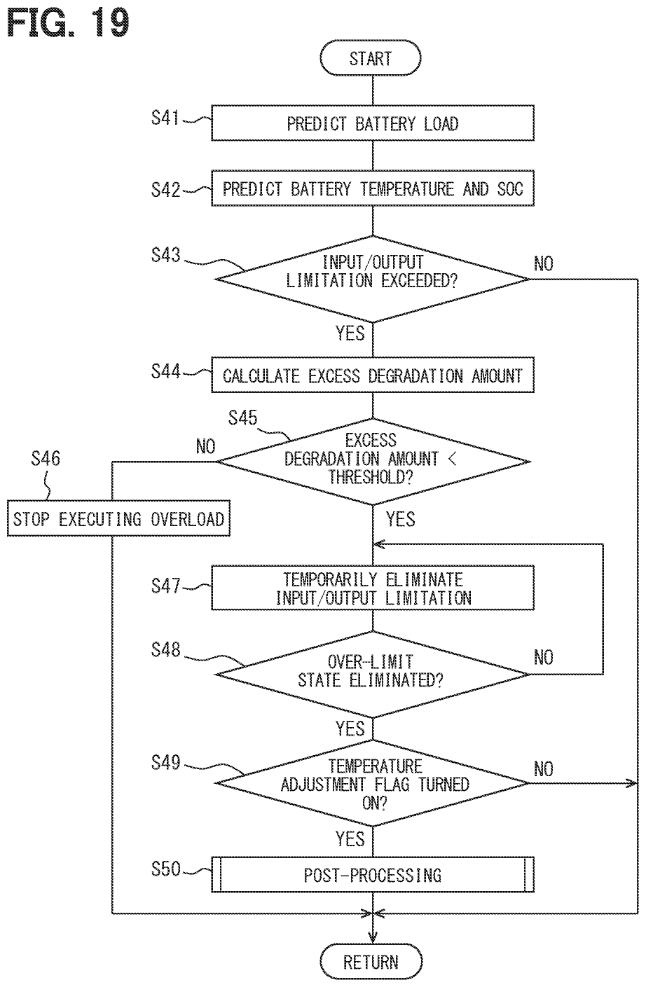

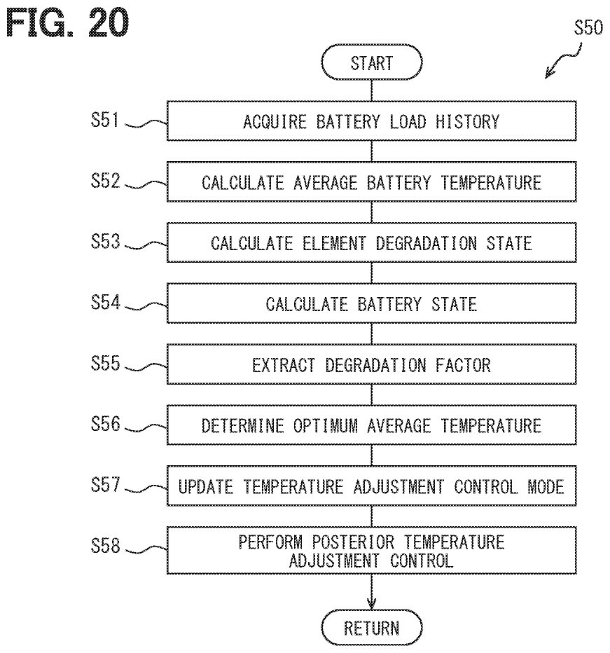

The description below explains the fifth embodiment that differs from the above-described embodiments by reference to FIGS. 19 and 20. The fifth embodiment differs from the above-described embodiments in the contents of the degradation suppression process. The basic configuration of the degradation suppression system 1 and the others are similar to those of the above-described embodiment and a repetitive description is omitted for simplicity.

The secondary battery 22 indicates a large thermal mass. The battery temperature T does not change immediately even when the refrigeration cycle device 31 starts the temperature adjustment control. The advance of degradation on the secondary battery 22 does not cause fatal damage even if the load exceeds for a short period.

High responsiveness to operation requests may be required for some devices and facilities that use the power of the secondary battery 22. For example, the refrigeration cycle device 31, when used for vehicle compartment air-conditioning, needs to respond instantaneously to the user's request. Otherwise, the comfort in the vehicle compartment may greatly degrade, increasing user dissatisfaction.

The degradation suppression system 1 according to the fifth embodiment balances the characteristics relating to the advance of degradation on the secondary battery 22 with the necessity for the operation of devices, for example. When the operation of devices is prioritized, the degradation suppression system 1 performs post-processing in consideration of the degradation factors. The description below explains the degradation suppression process of the degradation suppression system 1 according to the fifth embodiment by reference to FIGS. 19 and 20.

In step S41, as illustrated in FIG. 19, the degradation suppression system 1 predicts a battery load on the secondary battery 22. The battery load is predicted based on the operation situations of various devices mounted on the vehicle V, for example. In step S42, the degradation suppression system 1 predicts the battery temperature T and SOC of the secondary battery 22 by using the battery load predicted in step S41.

In step S43, the degradation suppression system 1 determines whether the input/output from the secondary battery 22 exceeds the input/output limitation due to the battery load. Specifically, it is determined whether the input to the secondary battery 22 exceeds the input limit and whether the output from the secondary battery 22 exceeds the output limit.

If the input/output limitation is not exceeded, there is no problem in application of the battery load predicted in step S41. Then, the degradation suppression system 1 allows inputs and outputs related to the battery load to terminate the degradation suppression process. If the input/output limitation is exceeded, the process proceeds to step S44.

In step S44, the degradation suppression system 1 calculates an excess degradation amount by using the battery load that exceeds the input/output limitation. The excess degradation amount signifies the degradation amount that occurs on the secondary battery 22 due to the load exceeding the input/output limitation. The excess degradation amount may be calculated based on a function using the load exceeding input/output limitation or the theory explained in the above-described embodiments. The vehicle ECU 10 executing step S44 is comparable to an excess degradation amount identification unit.

In step S45, the degradation suppression system 1 determines whether the excess degradation amount calculated in step S44 is smaller than a predetermined threshold. The threshold represents the degradation amount capable of compensating for the degradation of the secondary battery 22 corresponding to the excess degradation amount by executing the post-processing described later. The threshold signifies an allowable range relating to the application of an overload.

If the excess degradation amount is smaller than the threshold, the degradation suppression system 1 proceeds to step S47. If the excess degradation amount is not smaller than the threshold, the degradation suppression system 1 proceeds to step S46. The vehicle ECU 10 executing step S45 is comparable to an allowance determination unit.

In step S46, the degradation suppression system 1 stops application of the overload (such as an air conditioning operation by the refrigeration cycle device 31). This is because the application of the overload greatly advances the degradation of the secondary battery 22. After stopping the application of the overload, the degradation suppression system 1 terminates the degradation suppression process as is.

In step S47, the degradation suppression system 1 allows the application of overload and temporarily disables the input/output limitation specified for the secondary battery 22. By temporarily disabling the input/output limitation, the degradation suppression system 1 enables overload-related input/output from the secondary battery 22. The vehicle ECU 10 executing step S47 is comparable to a limit elimination unit. While temporarily disabling the input/output limitation, the degradation suppression system 1 turns on a posterior temperature adjustment flag that indicates the execution of post-processing to compensate for the degradation due to the application of the overload.

In step S48, the degradation suppression system 1 determines whether to eliminate an over-limit state where the input/output related to the battery load exceeds the input/output limitation. In other words, the degradation suppression system 1 determines whether the overload is terminated.

If the over-limit state is eliminated, the degradation suppression system 1 enables the input/output limitation, restores the state before step S45, and then proceeds to step S49. If the over-limit state is not eliminated, the degradation suppression system 1 returns to step S47 and maintains the state where the input/output limitation is temporarily disabled.

In step S49, the degradation suppression system 1 determines whether the posterior temperature adjustment flag is turned on. If the posterior temperature adjustment flag is turned on, the degradation suppression system 1 proceeds to step S50 to perform post-processing. If the posterior temperature adjustment flag is not turned on, the degradation suppression system 1 terminates the degradation suppression process as is.

After proceeding to step S50, the degradation suppression system 1 performs post-processing to compensate for the degradation of the secondary battery 22 due to the overload-related input/output. Specifically, the post-processing is executed according to the flowchart illustrated in FIG. 20.

As illustrated in FIG. 20, steps S51 through S57 included in the post-processing are equal to steps S1 through S7 according to the above-described first embodiment. The same process as in the first embodiment is performed based on the state of the secondary battery 22 at the time the overload is terminated. A detailed description of the process contents of steps S51 through S57 is omitted for brevity.

The post-processing specifies the optimum average temperature TaO as an optimal condition to minimize the future degradation amount of the secondary battery 22 according to the degradation amount and the configuration of degradation factors relating to the secondary battery 22 at the time the overload terminates. When specifying the optimum average temperature TaO, the degradation suppression system 1 corrects the optimum average temperature TaO according to the magnitude of the excess degradation amount calculated in step S44. For example, the correction amount of the optimum average temperature TaO is determined to increase as the excess degradation amount increases.

In step S58, the degradation suppression system 1 allows the refrigeration cycle device 31 to adjust the temperature as the posterior temperature adjustment control so that the average battery temperature Ta approximates the optimum average temperature TaO according to the temperature adjustment control mode updated in step S57.

The degradation suppression system 1 can suppress future degradation of the secondary battery 22 by performing the posterior temperature adjustment that reflects the degradation amount and the configuration of degradation factors relating to the secondary battery 22, including the application of overload. It is possible to compensate for the degradation due to the overload.

The degradation suppression system 1 according to the fifth embodiment can allow the application of overload under the condition that the post-processing is performed, despite an excess in the input/output limitation on the secondary battery 22. It is possible to appropriately balance satisfying the application of loads requiring the responsiveness to user requests with suppressing degradation of the secondary battery 22.

If the excess degradation amount is smaller than the threshold in step S45, the degradation suppression system 1 according to the fifth embodiment temporarily eliminates the input/output limitation on the secondary battery 22 in step S47. It is possible to allow the application of an overload that exceeds the input/output limitation on the secondary battery 22. The degradation suppression system 1 can handle loads that require responsiveness to user requests.

When the input/output limitation is temporarily eliminated, the degradation suppression system 1 performs post-processing in step S50. During the post-processing, the degradation suppression system 1 adjusts the temperature by using the refrigeration cycle device 31 so that the average battery temperature Ta approximates the optimum average temperature TaO determined through the use of the degradation amount and the configuration of degradation factors relating to the secondary battery 22 at the end of the overload.

The degradation suppression system 1 can compensate for the degradation due to the overload based on the posterior temperature adjustment control during the post-processing. It is possible to balance satisfying the load requiring responsiveness with suppressing degradation of the secondary battery 22.

When specifying the optimum average temperature TaO during the post-processing illustrated in FIG. 20, the degradation suppression system 1 corrects the optimum average temperature TaO according to the magnitude of the excess degradation amount calculated in step S44. For example, the correction amount of the optimum average temperature TaO is determined to increase as the excess degradation amount increases.

The mode of the posterior temperature adjustment control performed in step S58 reflects the magnitude of the excess degradation amount. The degradation suppression system 1 can provide the posterior temperature adjustment control to appropriately compensate for the overload-related degradation of the secondary battery 22.

The posterior temperature adjustment control is provided in step S58 by using the refrigeration cycle device 31 so that the average battery temperature Ta approximates the optimum average temperature TaO. The optimum average temperature is determined so that the future degradation amount of the secondary battery 22 decreases through the use of the degradation amount and the configuration of degradation factors relating to the secondary battery 22 after the overload terminates.

The degradation suppression system 1 provides the posterior temperature adjustment control reflecting the state of the secondary battery 22 after the overload terminates, making it possible to compensate for the overload-related degradation of the secondary battery 22 in an appropriate mode and suppress future degradation of the secondary battery 22.

### Modification of Fifth Embodiment

The fifth embodiment described above performs post-processing comparable to the contents corresponding to steps S1 through S8 in the first embodiment based on the state of the secondary battery 22 at the end of the overload.

The content of the post-processing in the fifth embodiment may conform to the content in the second embodiment, for example, if the processing content suppresses future degradation of the secondary battery 22, in terms of the state of the secondary battery 22, that is, the degradation amount and the configuration of degradation factors, at the end of the overload.

For example, the degradation suppression process according to the second embodiment is performed as the post-processing in step S50. In this case, the process whose content corresponds to steps S21 through S27 in FIG. 10 is performed based on the state of the secondary battery 22 at the end of the overload.

Also according to the modification of the fifth embodiment, the degradation suppression system 1 can provide effects similar to those of the fifth embodiment described above.

### Sixth Embodiment

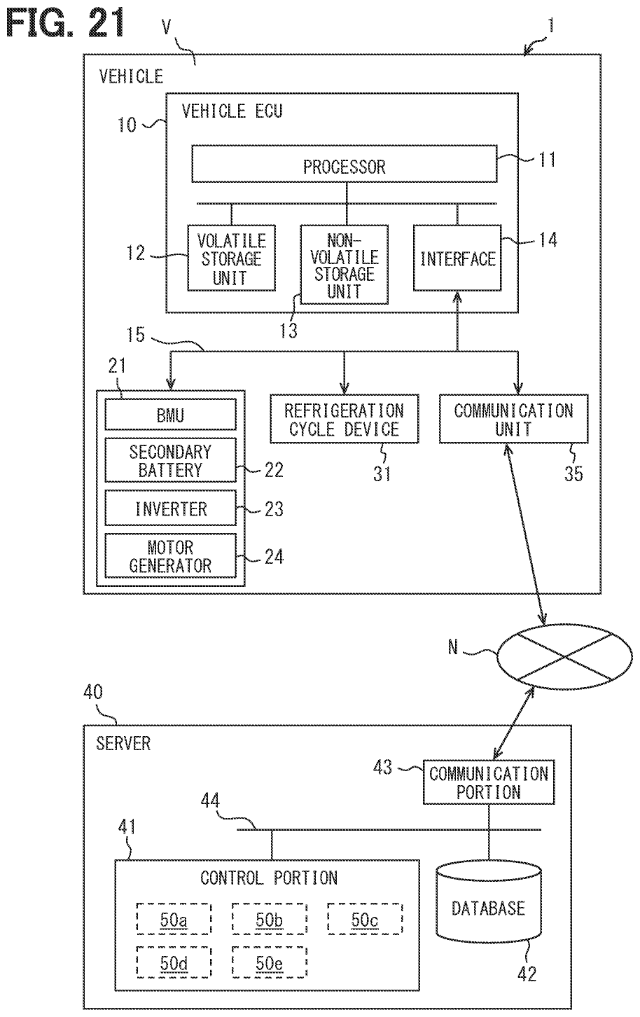

Next, the description below explains the sixth embodiment that differs from the above-described embodiments by reference to FIG. 21. The sixth embodiment differs from the above-described embodiments in the configuration of the degradation suppression system 1. The basic configuration of the degradation suppression system 1 and the others are similar to those of the above-described embodiment and a repetitive description is omitted for simplicity.

As illustrated in FIG. 21, the degradation suppression system 1 according to the sixth embodiment is configured to connect the vehicle V as an available device with the server 40 via network N to be capable of two-way communication. The degradation suppression system 1 according to the sixth embodiment performs the degradation suppression process to suppress degradation of the secondary battery 22 mounted on each of multiple vehicles V communicably connected via network N. The vehicle V according to the sixth embodiment is configured similarly to the above-described embodiments. A description of the configuration relating to the vehicle V is omitted for brevity.

The server 40 is configured by connecting a control unit 41, a database 42, and a communication portion 43 via a bus 44, for example. The control unit 41 is composed of a well-known microcomputer including CPU, ROM, and RAM, for example, and the peripheral circuits.

The CPU of the control unit 41 executes a control program stored in ROM to implement the functional portion of the degradation suppression system 1 according to the sixth embodiment. The degradation suppression system 1 according to the sixth embodiment allows the control unit 41 of the server 40 to implement a usage history acquisition unit 50a, a degradation amount estimation unit 50b, a degradation factor identification unit 50c, a suppression control unit 50d, and a degradation prediction unit

The database 42 is composed of information such as the battery load history, the degradation amount, the calendar degradation amount Za, and the cycle degradation amount Zb relating to the secondary battery 22 installed in each vehicle V. The communication portion 43 enables two-way data communication with each vehicle V via network N.

The description below explains example operations of the degradation suppression system 1 according to the sixth embodiment. The vehicle ECU 10 of the vehicle V outputs, to the server 40 via network N, a signal requesting the degradation suppression process along with the battery load history relating to the secondary battery 22 mounted on the vehicle V.

The control unit 41 of the server 40 receives the battery load history along with a signal requesting the degradation suppression process via network N. The control unit 41 at this time is comparable to the usage history acquisition unit 50a.

The control unit 41 estimates the degradation amount occurring on the secondary battery 22 of the vehicle V by using the received battery load history, for example. The degradation amount is estimated based on the same theory as in the embodiments described above. The control unit 41 at this time is comparable to the degradation amount estimation unit 50b.

After estimating the degradation amount of the secondary battery 22 of the vehicle V, the control unit 41 then uses the battery load history to identify multiple degradation factors (such as calendar degradation and cycle degradation) relating to the degradation. The degradation factors are identified also based on the same theory as in the above-described embodiments. The control unit 41 at this time is comparable to the degradation factor identification unit 50c.

The control unit 41 predicts the future degradation amount of the secondary battery 22 according to the degradation characteristics of the secondary battery 22 identified from the battery load history, and defines the optimum average temperature TaO, for example, so that the future degradation amount decreases. The control unit 41 at this time is comparable to the degradation prediction unit 50e.

The control unit 41 defines a temperature adjustment control mode of the refrigeration cycle device 31 so that the average battery temperature Ta approximates the optimum average temperature TaO. The control unit 41 transmits, to the vehicle V via network N, the determined temperature adjustment control mode of the refrigeration cycle device 31. The control unit 41 at this time is comparable to the suppression control unit 50d.

The vehicle ECU 10 receives the temperature adjustment control mode from the server 40, applies the received temperature adjustment control mode, and allows the refrigeration cycle device 31 to provide the temperature adjustment control over the secondary battery 22. The degradation suppression system 1 according to the sixth embodiment also provides the temperature adjustment control based on the degradation amount and the configuration of degradation factors relating to the secondary battery 22 in the vehicle V. It is possible to appropriately suppress future degradation of the secondary battery 22.

The degradation suppression system 1 according to the sixth embodiment transmits, to the server 40, the degradation amount and the configuration of degradation factors relating to the secondary batteries 22 in multiple vehicles V, for example. These pieces of information are stored in the database 42 and are used for information analysis, making it possible to specify a more appropriate degradation suppression control mode. For example, the control unit 41 of the server 40 may identify the optimum average temperature TaO by referencing various information stored in the database 42.

The degradation suppression system 1 according to the sixth embodiment can provide the effects similar to those of the above-described embodiments even when the vehicle V as an available device and the server 40 are connected to network N to be capable of two-way communication.

According to the sixth embodiment, the control unit 41 of the server 40 includes the functional portions such as the usage history acquisition unit 50a, the degradation amount estimation unit 50b, the degradation factor identification unit 50c, the suppression control unit 50d, and the degradation prediction unit 50e. However, the present disclosure is not limited thereto. The vehicle ECU 10 on the vehicle V may implement some of these functional portions and the control unit 41 of the server 40 may implement the remaining functional portions.

The present disclosure is not limited to the above-mentioned embodiments but may be variously modified within the spirit and scope of the disclosure, as will be described below.

It may be favorable to use, for example, units of years or seasons (or units of months) as the predetermined period for the average battery temperature Ta and the optimum average temperature TaO in the embodiments described above. However, the present disclosure is not limited thereto. The length of the period can be changed as appropriate under the condition that it is possible to ensure the amount of information necessary to identify the degradation amount or degradation factors.

According to the above-described embodiments, the refrigeration cycle device 31 represents the temperature adjustment unit. However, the present disclosure is not limited thereto. The temperature adjustment unit can be applied to various devices if it is possible to adjust the battery temperature T of the secondary battery 22.

The above-described embodiments directly apply the temperature adjustment control mode specified in the degradation suppression process, for example. However, the present disclosure is not limited thereto. It is also possible to allow the user to choose whether to apply the temperature adjustment control mode and, after receiving approval of the user, apply the specified temperature adjustment control mode.

The present disclosure has been described with reference to the embodiments but is not limited to the embodiments and structures. The present disclosure covers various modification examples and modifications within a commensurate scope. In addition, the category or the scope of the idea of the present disclosure covers various combinations or forms and moreover the other combinations or forms including only one element or more or less in the former.

What is claimed is:

1. A degradation suppression system comprising:
a secondary battery;
a usage history acquisition unit configured to acquire usage history information indicating a usage history of the secondary battery;
a degradation amount estimation unit configured to estimate a degradation amount of the secondary battery by using the usage history information acquired by the usage history acquisition unit;
a degradation factor identification unit configured to identify, for the degradation amount of the secondary battery estimated by the degradation amount estimation unit, a plurality of degradation factors, which relates to the degradation amount of the secondary battery, by using the usage history information; and
a suppression control unit configured to perform a control on the secondary battery to suppress degradation of the secondary battery according to a configuration of the degradation factors in degradation of the secondary battery.

2. The degradation suppression system according to claim 1, further comprising:
a degradation prediction unit configured to predict a future degradation amount of the secondary battery according to degradation characteristics of the secondary battery, which is identified by using the usage history information acquired by the usage history acquisition unit, wherein
the suppression control unit is configured to perform the control on the secondary battery to suppress degradation of the secondary battery by using
the configuration of the degradation factors in degradation of the secondary battery and
a future degradation amount of the secondary battery predicted by the degradation prediction unit.

3. The degradation suppression system according to claim 2, further comprising:
a temperature adjustment unit configured to adjust a temperature of the secondary battery, wherein
the suppression control unit is configured to control an operation of the temperature adjustment unit to satisfy an optimum battery temperature, which is derived from the configuration of the degradation factors in degradation of the secondary battery and a future degradation amount of the secondary battery and which decreases the future degradation amount of the secondary battery.

4. The degradation suppression system according to claim 3, wherein
the suppression control unit is configured to derive a target value for a period-based average temperature of the secondary battery by using
the period-based average temperature of the secondary battery included in the usage history information,
a composition ratio of the degradation factors in degradation of the secondary battery identified by the degradation factor identification unit, and
a target composition ratio, which is the composition ratio of the degradation factors that suppresses degradation of the secondary battery, and
the suppression control unit is configured to control the operation of the temperature adjustment unit by using, as the optimum battery temperature, the target value for the period-based average temperature as derived.

5. The degradation suppression system according to claim 4, wherein
the suppression control unit is configured to control the operation of the temperature adjustment unit to approximate the optimum battery temperature according to a deviation amount between the period-based average temperature of the secondary battery, which is included in the usage history information, and the target value of the period-based average temperature of the secondary battery.

6. The degradation suppression system according to claim 5, wherein,
the suppression control unit is configured to, when controlling the operation of the temperature adjustment unit, output a temperature adjustment request value, which indicates a degree of temperature adjustment by the temperature adjustment unit, based on a temperature adjustment request map whose argument is a present battery temperature of the secondary battery.

7. The degradation suppression system according to claim 4, wherein
the suppression control unit is configured to correct the target composition ratio according to a frequency of a depth of discharge of the secondary battery, which is included in the usage history information.

8. The degradation suppression system according to claim 3, wherein
the suppression control unit is configured to update a limitation mode of input/output of the secondary battery to satisfy the optimum battery temperature, which is derived from the configuration of the degradation factors in degradation of the secondary battery and the future degradation amount of the secondary battery and which decreases the future degradation amount of the secondary battery.

9. The degradation suppression system according to claim 8, wherein,
the suppression control unit is configured to, when updating the limitation mode of input/output of the secondary battery to satisfy the optimum battery temperature, control the temperature of the secondary battery by following the limitation mode of input/output of the secondary battery as updated.

10. The degradation suppression system according to claim 2, wherein
the suppression control unit is configured to derive an optimum input/output condition of the secondary battery, which is derived from the configuration of the degradation factors in degradation of the secondary battery and a future degradation amount of the secondary battery and which decreases the future degradation amount of the secondary battery, and
the secondary battery is used, such that the optimum input/output condition is satisfied.

11. The degradation suppression system according to claim 10, wherein
the suppression control unit is configured to
update an input/output range of the secondary battery, such that the optimum input/output condition is satisfied, and
control input and output of the secondary battery in the input/output range as updated.

12. The degradation suppression system according to claim 10, wherein
the suppression control unit is configured to
balance a power supply with a power consumption, and
control at least one of input and output of the secondary battery, such that the optimum input/output condition is satisfied.

13. The degradation suppression system according to claim 2, further comprising:
an excess degradation amount identification unit configured to identify an excess degradation amount, which is a degradation amount caused by a load on the secondary battery that exceeds an input/output limitation specified for the secondary battery;
an allowance determination unit configured to determine whether to allow application of a load on the secondary battery according to the excess degradation amount, which is identified by the excess degradation amount identification unit, and a predetermined allowable range; and
a limit elimination unit configured to temporarily eliminate the input/output limitation on the secondary battery and allow application of the load on the secondary battery on determination of the allowance determination unit that allows application of the load on the secondary battery, wherein
the suppression control unit is configured to
terminate the application of the load on the secondary battery, which is performed by temporary eliminating the input/output limitation, and restore the input/output limitation, and
subsequently perform a degradation suppression control to suppress degradation of the secondary battery to satisfy an optimal condition, which is derived from the configuration of the degradation factors in degradation of the secondary battery and a future degradation amount of the secondary battery, and which decreases the future degradation amount of the secondary battery.

14. The degradation suppression system according to claim 13, wherein
the suppression control unit is configured to, when the limit elimination unit terminates application of the load on the secondary battery, which is performed by temporarily eliminating the input/output limitation, perform the degradation suppression control in a mode corresponding to a magnitude of the excess degradation amount identified by the excess degradation amount identification unit.

15. The degradation suppression system according to claim 14, further comprising:
a temperature adjustment unit configured to adjust a temperature of the secondary battery, wherein
the suppression control unit is configured to perform the degradation suppression control by controlling an operation of the temperature adjustment unit to satisfy an optimum battery temperature, which is derived from the configuration of the degradation factors in degradation of the secondary battery and a future degradation amount of the secondary battery and which decreases the future degradation amount of the secondary battery.

16. The degradation suppression system according to claim 14, wherein
the suppression control unit is configured to perform the degradation suppression control by deriving an optimum input/output condition of the secondary battery, which is derived from the configuration of degradation factors of degradation on the secondary battery and the future degradation amount of the secondary battery and which decreases the future degradation amount of the secondary battery, and
the secondary battery is used, such that the optimum input/output condition is satisfied.

17. The degradation suppression system according to claim 1, further comprising:
an available device configured to use the secondary battery; and
a server that includes the usage history acquisition unit, the degradation amount estimation unit, the degradation factor identification unit, and the suppression control unit and is connected to the available device via a network connected to be capable of two-way communication.

18. A degradation suppression system comprising:
a secondary battery; and
a processor configured to
acquire usage history information indicating a usage history of the secondary battery,
estimate a degradation amount of the secondary battery by using the usage history information as acquired,
identify, for the degradation amount of the secondary battery as estimated, a plurality of degradation factors, which relates to the degradation amount of the secondary battery, by using the usage history information, and
perform a control on the secondary battery to suppress a degradation of the secondary battery according to a configuration of the degradation factors in degradation of the secondary battery.
